(19) United States
(12) Patent Application Publication
(10) Pub. No.: US 2013/0051967 A1
(43) Pub. Date: Feb. 28, 2013

(54) SUBSTRATE INVERTING APPARATUS, SUBSTRATE HANDLING METHOD, AND SUBSTRATE PROCESSING APPARATUS

(71) Applicant: Ryo MURAMOTO, Kyoto (JP)

(72) Inventor: Ryo MURAMOTO, Kyoto (JP)

(21) Appl. No.: 13/556,528

(22) Filed: Jul. 24, 2012

(30) Foreign Application Priority Data
Aug. 26, 2011 (JP) 2011-184881

(51) Int. Cl. H01L 21/68

(52) U.S. Cl. 414/758; 414/816

(57) ABSTRACT

A substrate inverting apparatus includes a plurality of first lower guides supporting a substrate in a horizontal orientation by contact of first lower inclined portions with a peripheral edge portion of the substrate, a plurality of first upper guides that, by contact of first upper inclined portions with the peripheral edge portion of the substrate, clamp the substrate in cooperation with the plurality of first lower guides, a guide moving mechanism that moves the plurality of first upper guides and first lower guides horizontally, and a guide rotating unit that inverts the substrate by rotating the plurality of first upper guides and first lower guides around a horizontally extending inversion axis.

### BACKGROUND OF THE INVENTION

1. Field of the Invention

The present invention relates to a substrate inverting apparatus and a substrate handling method for inverting a substrate and a substrate processing apparatus for processing a substrate. Examples of substrates include semiconductor wafers, substrates for liquid crystal displays, substrates for plasma displays, substrates for FEDs (Field Emission Displays), substrates for optical disks, substrates for magnetic disks, substrates for magneto-optical disks, substrates for photomasks, ceramic substrates, substrates for solar cells, etc.

2. Description of Related Art

In a manufacturing process for a semiconductor device or a liquid crystal display, a substrate processing apparatus for processing substrates, such as semiconductor wafers, glass substrates for liquid crystal displays, is used. For example, a substrate processing apparatus described in United States Patent Application Publication Number US2008/0156357A1 includes a reversing unit that reverses a substrate by rotating the substrate around a horizontal axis. The reversing unit includes a fixed plate supported horizontally, a movable plate facing the fixed plate, a cylinder moving the movable plate in parallel vertically, and a rotary actuator rotating the fixed plate and the movable plate around the horizontal axis.

When a substrate is to be reversed, the substrate that has been conveyed into a space between the fixed plate and the movable plate is supported by the fixed plate via a plurality of supporting pins mounted on the fixed plate. Thereafter, the cylinder lowers the movable plate to make the movable plate approach the fixed plate. The substrate supported by the fixed plate is thereby clamped from above and below by the plurality of supporting pins mounted on the fixed plate and a plurality of supporting pins mounted on the movable plate. Thereafter, the rotary actuator rotates the fixed plate and the movable plate around the horizontal axis and the substrate clamped by the fixed plate and the movable plate is thereby reversed.

With the reversing unit described in US 2008/0156357A1, the movable plate moves vertically and thus a space for movement of the movable plate must be secured above and below the movable plate. The reversing unit is thereby increased in height and the reversing unit is thus enlarged.

### SUMMARY OF THE INVENTION

A preferred embodiment of the present invention provides a substrate inverting apparatus and a substrate handling method by which enlargement of the substrate inverting apparatus can be suppressed or prevented.

Further, a preferred embodiment of the present invention provides a substrate processing apparatus that includes the substrate inverting apparatus by which enlargement thereof can be suppressed or prevented.

A substrate inverting apparatus according to a preferred embodiment of the present invention includes a plurality of first lower guides respectively having a plurality of first lower inclined portions inclined obliquely downward toward a vertically extending reference line and supporting a substrate in a horizontal orientation by contacting of the plurality of first lower inclined portions with a peripheral edge portion of the substrate, a plurality of first upper guides respectively having a plurality of first upper inclined portions inclined obliquely upward toward the reference line and clamping the substrate in cooperation with the plurality of first lower guides by contacting of the plurality of first upper inclined portions with the peripheral edge portion of the substrate at positions higher than the positions at which the plurality of first lower inclined portions contact the peripheral edge portion of the substrate, a guide moving mechanism that moves the plurality of first upper guides horizontally and moves the plurality of first lower guides horizontally, and a guide rotating unit that rotates the plurality of first upper guides and the plurality of first lower guides around a horizontally extending inversion axis to invert the substrate clamped by the plurality of first upper guides and the plurality of first lower guides.

With this arrangement, the first lower inclined portions of the plurality of first lower guides contact the peripheral edge portion of the substrate and the first upper inclined portions of the plurality of first upper guides contact the peripheral edge portion of the substrate at the positions above the positions at which the first lower inclined portions contact the peripheral edge portion of the substrate. The substrate is thereby clamped in the horizontal orientation by the plurality of first upper guides and the plurality of first lower guides. In the state where the plurality of first upper guides and the plurality of first lower guides clamp the substrate, the guide rotating unit rotates the plurality of first upper guides and the plurality of first lower guides by 180 degrees around the inversion axis. A position of a top surface of the substrate and a position of a rear surface of the substrate are thereby interchanged and the substrate is inverted.

The first lower inclined portions of the first lower guides are inclined obliquely downward toward the vertically extending reference line. The plurality of first lower guides can thus support a substrate in the horizontal orientation by contacting of the plurality of first lower inclined portions with the peripheral edge portion of the substrate. Further, the guide moving mechanism can withdraw the plurality of first upper guides by moving the plurality of first upper guides horizontally. A substrate conveying robot that conveys a substrate can place the substrate on the plurality of first lower guides or receive a substrate supported by the plurality of first lower guides in the state where the plurality of first upper guides are withdrawn.

Also, the first upper inclined portions of the first upper guide are inclined obliquely upward toward the reference line, and thus when the guide rotating unit rotates the plurality of first upper guides and the plurality of first lower guides by 180 degrees around the inversion axis, the first upper inclined portions change from a downwardly facing state to an upwardly facing state. In the state where the first upper inclined portions face upward, the plurality of first upper guides can support a substrate in the horizontal orientation by contacting of the plurality of first upper inclined portions with the peripheral edge portion of the substrate. The substrate conveying robot can thus convey a substrate onto the plurality of first upper guides or convey a substrate out from the plurality of first upper guides even when the plurality of first lower inclined portions are in the downwardly facing state.

The substrate conveying robot can thus convey in and convey out a substrate regardless of which of the first upper inclined portions and the first lower inclined portions are in the downwardly facing state because the respective guides are provided with the inclined portions that are inclined with respect to a horizontal plane. Further, in the state where the substrate is supported in the horizontal orientation by the first upper guides or the first lower guides, the guide moving mechanism can move the withdrawn plurality of guides horizontally to clamp the substrate in the horizontal orientation by the plurality of first upper guides and first lower guides. Yet further, spaces for movement of the guides do not have to be provided above and below the guides because the guide moving mechanism moves the first upper guides and the first lower guides horizontally. The substrate inverting apparatus can thus be reduced in height in comparison to an arrangement in which the guides perform clamping upon being moved vertically. Enlargement of the substrate inverting apparatus can thereby be suppressed or prevented.

Preferably, the substrate inverting apparatus according to the preferred embodiment of the present invention further includes a plurality of holding members, each holding the first upper guide and the first lower guide and being rotated around the inversion axis by the guide rotating unit.

With this arrangement, the guide rotating unit rotates the plurality of holding members around the inversion axis. The plurality of holding members hold the plurality of first upper guides and the plurality of first lower guides, and thus when the guide rotating unit rotates the plurality of holding members around the inversion axis, the plurality of first upper guides and the plurality of first lower guides also rotate around the inversion axis. A plurality of members that individually couple the plurality of first upper guides and the plurality of first lower guides with the guide rotating unit thus do not have to be provided. Enlargement of the substrate inverting apparatus can thus be suppressed or prevented.

The substrate inverting apparatus according to the preferred embodiment of the present invention may further include a plurality of rotating shafts respectively coupled to the plurality of holding members and rotatable around the inversion axis. In this case, the guide rotating unit may be coupled to any one of the plurality of rotating shafts.

With this arrangement, a driving force of the guide rotating unit (driving force around the inversion axis) is input into any one of the rotating shafts (driving side rotating shaft). The driving force input into the driving side rotating shaft is transmitted, via the holding member (driving side holding member) coupled to the driving side rotating shaft, to the guides held by the driving side holding member. Thus, in the state where a substrate is being clamped by the plurality of guides, the driving force of the guide rotating unit is transmitted from the guides held by the driving side holding member and via the substrate to the guides held by another holding member (driven side holding member). The driving force of the guide rotating unit is thereby transmitted from the driving side holding member to the driven side holding member and the plurality of holding members and the plurality of rotating shafts rotate around the inversion axis. The guide rotating unit is thus coupled to only any one of the rotating shafts and thus the substrate inverting apparatus can be reduced in size in comparison to an arrangement where the guide rotating unit is coupled to the respective rotating shafts. Enlargement of the substrate inverting apparatus can thereby be suppressed or prevented.

Also, with the substrate inverting apparatus according to the preferred embodiment of the present invention, the plurality of first upper guides may be disposed respectively above the plurality of first lower guides. With this arrangement, the first upper guides and the first lower guides are overlapped in a plan view because the plurality of first upper guides are disposed respectively above the plurality of first lower guides. An area occupied by the first upper guides and the first lower guides in a plan view can thereby be reduced. Enlargement of the substrate inverting apparatus can thereby be suppressed or prevented.

The substrate inverting apparatus according to the preferred embodiment of the present invention may further include a plurality of second lower guides respectively having a plurality of second lower inclined portions inclined obliquely downward toward the reference line and supporting a substrate, disposed at a different height from the substrate clamped by the plurality of first upper guides and the plurality of first lower guides, in a horizontal orientation by contacting of the plurality of second lower inclined portions with a peripheral edge portion of the substrate, and a plurality of second upper guides respectively having a plurality of second upper inclined portions inclined obliquely upward toward the reference line and clamping the substrate in cooperation with the plurality of second lower guides by contacting of the plurality of second upper inclined portions with the peripheral edge portion of the substrate at positions above the positions at which the plurality of second lower inclined portions contact the peripheral edge portion of the substrate. Preferably in this case, the guide moving mechanism moves the plurality of second upper guides horizontally and moves the second lower guides horizontally, and the guide rotating unit rotates the plurality of second upper guides and the plurality of second lower guides around the inversion axis to invert the substrate clamped by the plurality of second upper guides and the plurality of second lower guides.

With this arrangement, the second lower inclined portions of the plurality of second lower guides contact the peripheral edge portion of the substrate disposed at the different height from the substrate clamped by the plurality of first upper guides and first lower guides. Further, the second upper inclined portions of the plurality of second upper guides contact the peripheral edge portion of the substrate at the positions above the positions at which the second lower inclined portions contact the peripheral edge portion of the substrate. The substrate is thereby clamped in the horizontal orientation. The substrate clamped by the plurality of second upper guides and second lower guides can thus be inverted by rotating the plurality of second upper guides and second lower guides by 180 degrees around the inversion axis. The substrate clamped by the plurality of first upper guides and first lower guides and the substrate clamped by the plurality of second upper guides and second lower guides can thereby be inverted at the same time. That is, a plurality of substrates can be inverted at the same time.

Further, in the same manner as with the first upper guides and the first lower guides, the second upper guides and the second lower guides are provided with inclined portions (second upper inclined portions or second lower inclined portions) that are inclined with respect to the horizontal plane, and thus the substrate conveying robot can perform conveying-in and conveying-out of the substrate regardless of which of the second upper inclined portions and the second lower inclined portions are in the downwardly facing state. Moreover, the guide moving mechanism not only moves the first upper guides and the first lower guides horizontally but also moves the second upper guides and the second lower guides horizontally and thus spaces for movement of the guides do not have to be provided above and below the second upper guides and the second lower guides. An interval (interval in a vertical direction) between the first upper guides plus first lower guides and the second upper guides plus second lower guides can thus be made small. The height of the substrate inverting apparatus can thus be reduced significantly. Enlargement of the substrate inverting apparatus can thereby be suppressed or prevented.

Also, preferably, the substrate inverting apparatus according to the preferred embodiment of the present invention further includes a plurality of holding members, each holding the first upper guide, the first lower guide, the second upper guide, and the second lower guide and being rotated around the inversion axis by the guide rotating unit.

With this arrangement, the guide rotating unit rotates the plurality of holding members around the inversion axis. Each of the plurality of holding members holds the first upper guide, the first lower guide, the second upper guide, and the second lower guide and thus when the guide rotating unit rotates the plurality of holding members around the inversion axis, the first upper guides, the first lower guides, the second upper guides, and the second lower guides also rotate around the inversion axis. A plurality of members that individually couple the first upper guides, the first lower guides, the second upper guides, and the second lower guides with the guide rotating unit thus do not have to be provided. Enlargement of the substrate inverting apparatus can thus be suppressed or prevented.

Also, the substrate inverting apparatus according to the preferred embodiment of the present invention may further include a plurality of rotating shafts respectively coupled to the plurality of holding members and rotatable around the inversion axis. In this case, the guide rotating unit may be coupled to any one of the plurality of rotating shafts.

With this arrangement, the driving force of the guide rotating unit (driving force around the inversion axis) is input into any one of the rotating shafts (driving side rotating shaft). The driving force input into the driving side rotating shaft is transmitted, via the holding member (driving side holding member) coupled to the driving side rotating shaft, to the guides held by the driving side holding member. Thus, in the state where a substrate is being clamped by the plurality of guides, the driving force of the guide rotating unit is transmitted from the guides held by the driving side holding member and via the substrate to guides held by another holding member (driven side holding member). The driving force of the guide rotating unit is thereby transmitted from the driving side holding member to the driven side holding member and the plurality of holding members and the plurality of rotating shafts rotate around the inversion axis. The guide rotating unit is thus coupled to only any one of the rotating shafts and thus the size of the substrate inverting apparatus can be reduced in comparison to an arrangement where the guide rotating unit is coupled to the respective rotating shafts. Enlargement of the substrate inverting apparatus can thereby be suppressed or prevented.

The guide moving mechanism may include a first upper guide moving unit horizontally moving the first upper guides, a second upper guide moving unit horizontally moving the second upper guides, a first lower guide moving unit horizontally moving the first lower guides, and a second lower guide moving unit horizontally moving the second lower guides.

With this arrangement, the four types of guide moving mechanisms (first upper guide moving unit, first lower guide moving unit, second upper guide moving unit, and second lower guide moving unit) respectively corresponding to the four types of guides (first upper guides, first lower guides, second upper guides, and second lower guides) are provided. Each of the four types of guides can thus be moved horizontally independently of the other types of guides.

The guide moving mechanism may include an upper guide moving module horizontally moving the first upper guides and the second upper guides and a lower guide moving module horizontally moving the first lower guides and the second lower guides.

With this arrangement, the upper guide moving module corresponding to the two types of upper guides (first upper guides and second upper guides) and the lower guide moving module corresponding to the two types of lower guides (first lower guides and second lower guides) are provided. The guide moving mechanism can thus be reduced in number in comparison to an arrangement in which a guide moving mechanism is provided according to each type of guide. Enlargement of the substrate processing apparatus can thereby be suppressed or prevented.

The first upper guides, the first lower guides, the second upper guides, and the second lower guides may be rotatable around the inversion axis relative to the guide moving mechanism.

With this arrangement, the guide rotating unit does not have to rotate the guide moving mechanism around the inversion axis to invert the substrate because the first upper guides, the first lower guides, the second upper guides, and the second lower guides are rotatable around the inversion axis relative to the guide moving mechanism. A mass of a rotating body rotated by the guide rotating unit can thus be reduced. A compact unit of low output can thus be used as the guide rotating unit. Enlargement of the substrate inverting apparatus can thereby be suppressed or prevented.

Also, the substrate inverting apparatus according to the preferred embodiment of the present invention may further include a guide raising/lowering unit that moves the first upper guides plus the first lower guides and the second upper guides plus the second lower guides in mutually opposite directions in regard to the vertical direction.

With this arrangement, the guide raising/lowering unit raises and lowers the first upper guides and the first lower guides. Further, the guide raising/lowering unit raises and lowers the second upper guides and the second lower guides. The guide raising/lowering unit moves the first upper guides plus the first lower guides and the second upper guides plus the second lower guides in mutually opposite directions in regard to the vertical direction. The interval (interval in the vertical direction) between the first upper guides plus the first lower guides and the second upper guides plus the second lower guides is thereby increased or decreased.

As shall be described later, the guide raising/lowering unit is capable of moving a substrate from the substrate inverting apparatus to the substrate conveying robot and transferring a substrate from the substrate conveying robot to the substrate inverting apparatus by raising and lowering the respective guides and without moving two hands of the substrate conveying robot. Time required for transfer of the substrate can thereby be shortened. Particularly, in a case where the guide raising/lowering unit performs raising/lowering of the first upper guides and the first lower guides at the same time as performing raising/lowering of the second upper guides and the second lower guides, the movement of a substrate from the substrate inverting apparatus to the substrate conveying robot and the transfer of a substrate from the substrate conveying robot to the substrate inverting apparatus are performed at the same time to enable the time required for transfer of the substrates to be shortened further.

A substrate processing apparatus according to a preferred embodiment of the present invention preferably includes the substrate inverting apparatus having the characteristics described above and a substrate conveying robot performing conveying-in of a substrate to the substrate inverting apparatus and conveying-out of a substrate from the substrate inverting apparatus.

With this arrangement, the substrate conveying robot conveys a substrate into the substrate inverting apparatus. The substrate conveying robot conveys out the substrate that has been inverted by the substrate inverting apparatus from the substrate inverting apparatus. The substrate conveying robot can thus transfer a substrate in both a state where a top surface of the substrate is faced upward and a state where a top surface of the substrate is faced downward.

Also, a preferred embodiment of the present invention provides a substrate handling method including a first clamping step (A) of clamping a substrate by a plurality of first upper guides and a plurality of first lower guides, and a first inverting step (B) of inverting the substrate clamped by the first upper guides and the first lower guides by rotating the plurality of first upper guides and the plurality of first lower guides around a horizontally extending inversion axis. The clamping step includes the steps of horizontally moving the plurality of first lower guides, having a plurality of first lower inclined portions inclined obliquely downward toward a vertically extending reference line, to make the plurality of first lower inclined portions contact a peripheral edge portion of the substrate (A1) and horizontally moving the plurality of first upper guides, having a plurality of first upper inclined portions inclined obliquely upward toward the reference line, to make the plurality of first upper inclined portion contact the peripheral edge portion of the substrate at positions higher than the positions at which the plurality of first lower inclined portions contact the peripheral edge portion of the substrate (A2). With the present substrate handling method, spaces for moving the first upper guides and the first lower guides do not have to be provided above and below the guides.

The aforementioned and other objects, features, and effects of the present invention shall be clarified by the following description of preferred embodiments with reference to the accompanying drawings.

### BRIEF DESCRIPTION OF THE DRAWINGS

FIG. 1 is a schematic side view of a layout of a substrate processing apparatus according to a first preferred embodiment of the present invention.

FIG. 2 is a schematic front view for describing an internal arrangement of an inverting path according to the first preferred embodiment of the present invention.

FIG. 3 is a schematic plan view of the inverting path according to the first preferred embodiment of the present invention.

FIG. 4 is a schematic view of the inverting path as viewed from a direction of an arrow IV shown in FIG. 2.

FIG. 5 is a front view of an example of a first upper guide and a first lower guide.

FIGS. 6A to 6K are schematic views of an example of operations performed during inversion of a substrate by the inverting path.

FIG. 7 is a schematic front view for describing an internal arrangement of an inverting path according to a second preferred embodiment of the present invention.

FIG. 8 is a schematic view of the inverting path as viewed from a direction of an arrow VIII shown in FIG. 7.

FIG. 9 is a schematic front view for describing an internal arrangement of an inverting path according to a third preferred embodiment of the present invention.

FIG. 10 is a schematic view of the inverting path as viewed from a direction of an arrow X shown in FIG. 9.

FIG. 11 is a schematic front view for describing an arrangement of an inverting path according to a fourth preferred embodiment of the present invention.

FIG. 12 is a schematic view of the inverting path as viewed from a direction of an arrow XII shown in FIG. 11.

FIGS. 13A to 13J are schematic views of an example of operations performed during inversion of a substrate by the inverting path.

FIG. 14 is a schematic front view for describing an arrangement of an inverting path according to a fifth preferred embodiment of the present invention.

FIG. 15 is a schematic plan view for describing the arrangement of the inverting path according to the fifth preferred embodiment of the present invention.

FIG. 16 is an enlarged view of a portion of FIG. 14.

### DETAILED DESCRIPTION OF THE PREFERRED EMBODIMENTS

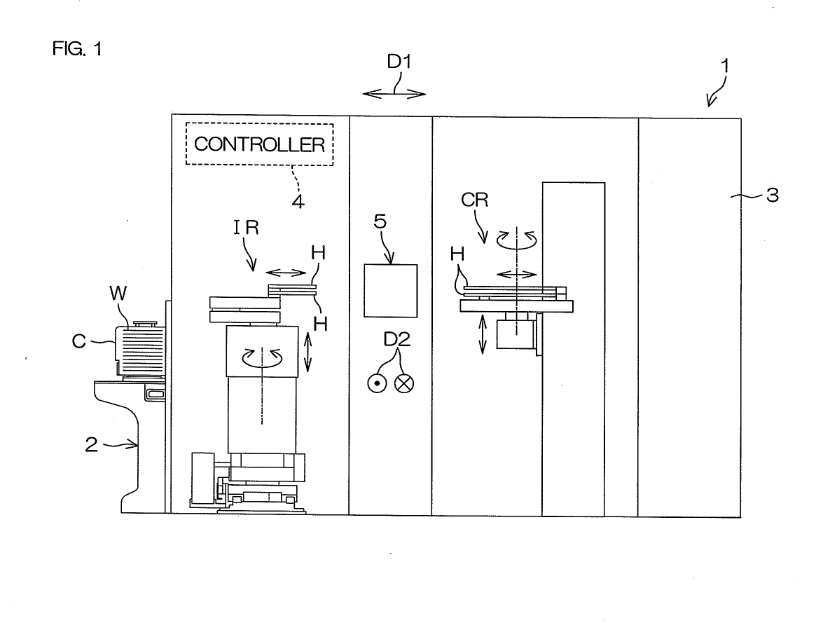

FIG. 1 is a schematic side view of a layout of a substrate processing apparatus 1 according to a first preferred embodiment of the present invention.

The substrate processing apparatus 1 is a one-by-one type substrate processing apparatus that processes circular substrates W, such as semiconductor wafers. The substrate processing apparatus 1 includes a carrier holding unit 2 arranged to hold a plurality of carriers C that house the substrates W, a processing unit 3 arranged to process each substrate W, and a controller 4 (control unit) arranged to control operations of apparatuses and opening/closing of valves provided in the substrate processing apparatus 1. The substrate processing apparatus 1 further includes an inverting path 5 (substrate inverting apparatus) disposed between the carrier holding unit 2 and the processing unit 3, an indexer robot IR (substrate conveying robot) arranged to convey a substrate W between the carrier holding unit 2 and the inverting path 5, and a center robot CR (substrate conveying robot) arranged to convey a substrate W between the processing unit 3 and the inverting path 5. The inverting path 5 is a substrate inverting apparatus that inverts a substrate W.

The indexer robot IR is disposed between the carrier holding unit 2 and the inverting path 5. The center robot CR is disposed between the processing unit 3 and the inverting path 5. The indexer robot IR and the center robot CR face the inverting path 5 in a horizontal conveying direction D1. The indexer robot IR performs a conveying-in operation of conveying a substrate W into any one of the carriers C or the inverting path 5 and a conveying-out operation of conveying out a substrate W from any one of the carriers C or the inverting path 5. The center robot CR performs a conveying-in operation of conveying a substrate W to the processing unit 3 or the inverting path 5 and a conveying-out operation of conveying out a substrate W from the processing unit 3 or the inverting path 5.

The indexer robot IR has two hands H that hold substrates W horizontally at mutually different heights. The indexer robot IR moves the two hands H horizontally and independently of each other. Further, the indexer robot IR raises and lowers the two hands H and rotates the two hands H around a vertical axis. Likewise, the center robot CR has two hands H that hold substrates W horizontally at mutually different heights. The center robot CR moves the two hands H horizontally and independently of each other. Further, the center robot CR raises and lowers the two hands H and rotates the two hands H around a vertical axis.

In each carrier C, a substrate W is housed in a state where a top surface of the substrate W that is a device forming surface is faced upward. The controller 4 makes the index robot IR convey a substrate W with its top surface facing upward from a carrier C to the inverting path 5. The controller 4 then makes the inverting path 5 invert the substrate W. A rear surface of the substrate W is thereby faced upward. Thereafter, the controller 4 makes the center robot CR convey the substrate W with the rear surface facing upward from the inverting path 5 to the processing unit 3. The controller 4 then makes the rear surface of the substrate W be processed by the processing unit 3.

After the rear surface of the substrate W has been processed, the controller 4 makes the center robot CR convey the substrate W with the rear surface facing upward from the processing unit 3 to the inverting path 5. The controller 4 then makes the inverting path 5 invert the substrate W. The top surface of the substrate W is thereby faced upward. Thereafter, the controller 4 makes the indexer robot IR convey the substrate W with the top surface facing upward from the inverting path 5 to the carrier C. The processed substrate W is thereby housed in the carrier C. The controller 4 makes the indexer robot IR, etc., execute the series of operations repeatedly to process the plurality of substrates W one by one.

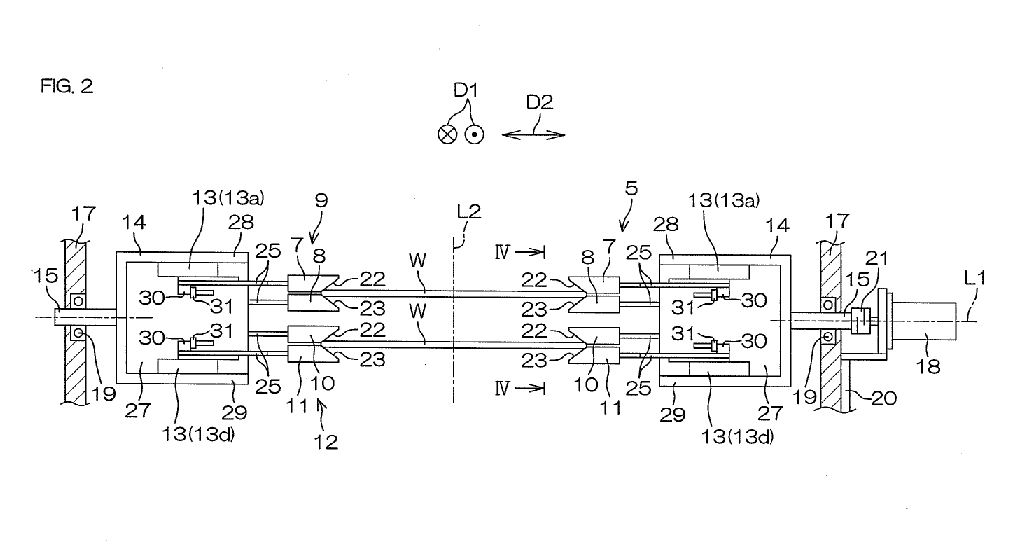

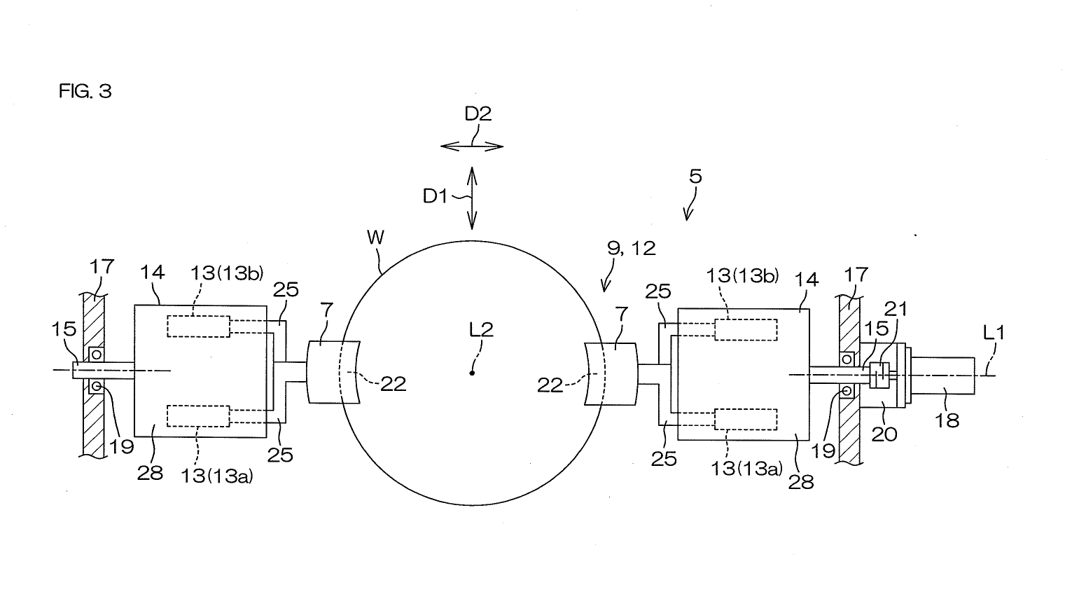

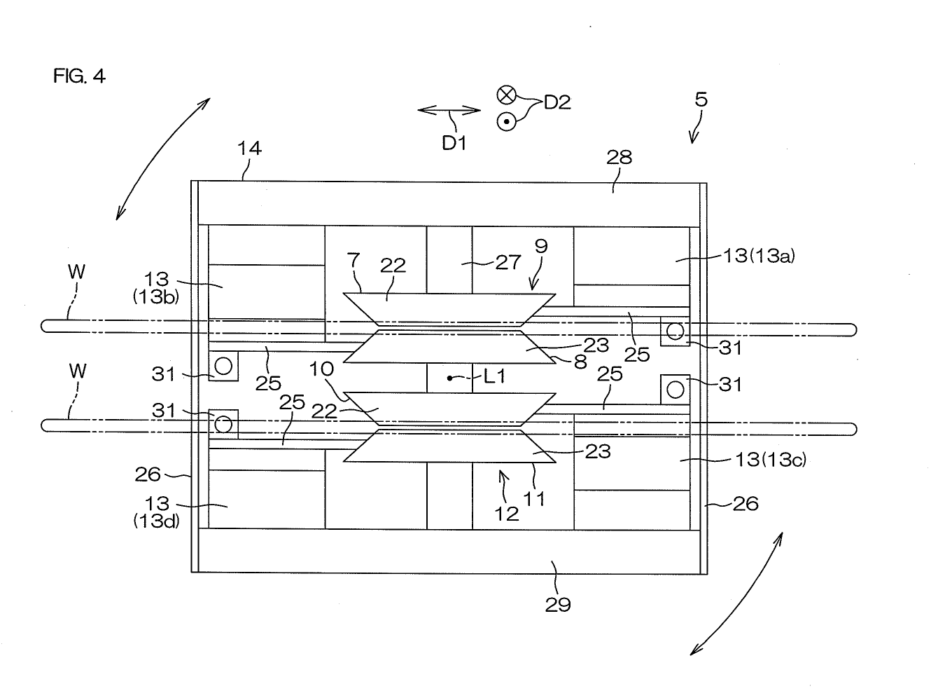

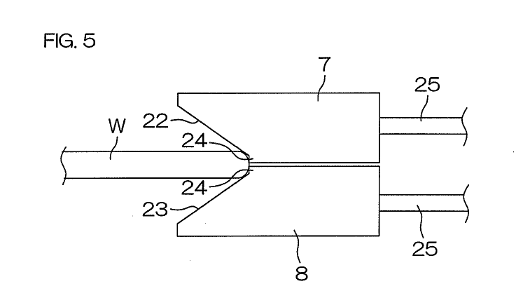

FIG. 2 is a schematic front view for describing an internal arrangement of the inverting path 5 and is a view of the inverting path 5 as viewed from a conveying direction D1. FIG. 2 shows a state where side walls 26 of holding boxes 14 are removed. Also, FIG. 3 is a schematic plan view of the inverting path 5. FIG. 4 is a schematic view of the inverting path 5 as viewed from a direction of an arrow IV shown in FIG. 2. FIG. 5 is a front view of an example of a first upper guide 7 and a first lower guide 8.

As shown in FIG. 2, the inverting path 5 has a first chuck 9 that includes two first upper guides 7 and two first lower guides 8, and a second chuck 12 that includes two second upper guides 10 and two second lower guides 11. The first chuck 9 and the second chuck 12 are arranged to clamp substrates W in horizontal orientations at mutually different heights. The inverting path 5 further includes a plurality of cylinders 13 (guide moving mechanisms) that horizontally move the guides 7, 8, 10, and 11, two holding boxes 14 (holding members) holding the plurality of cylinders 13, two rotating shafts 15 coupled respectively to the two holding boxes 14, two supporting plates 17 supporting the two rotating shafts 15 in a manner enabling rotation around a horizontal inversion axis L1, and an electric motor 18 (guide rotating unit) rotating the guides 7, 8, 10, and 11 around the inversion axis L1.

As shown in FIG. 2, the supporting plates 17 are supported in vertical orientations. The two supporting plates 17 face each other across an interval in a horizontally extending facing direction D2 (horizontal direction orthogonal to the conveying direction D1). The two holding boxes 14 are disposed at inner sides of the two supporting plates 17 (between the two supporting plates 17). The first chuck 9 and the second chuck 12 are disposed between the two holding boxes 14. The two rotating shafts 15 respectively extend outward from the two supporting boxes 14. Each rotating shaft 15 is supported by the supporting plate 17 via a bearing 19. The two rotating shafts 15 extend in the facing direction D2 at a height between the first chuck 9 and the second chuck 12. The two rotating shafts 15 are disposed along the same horizontal axis. The inversion axis L1 is a horizontal axis that passes through the two rotating shafts 15. The electric motor 18 is disposed outside the two supporting plates 17. The electric motor 18 is mounted on one of the supporting plates 17 by a mounting bracket 20. An output shaft of the electric motor 18 is coupled to one of the rotating shafts 15 by a joint 21. The electric motor 18 is controlled by the controller 4.

As shown in FIG. 2, the first chuck 9 is arranged to hold a substrate W in a horizontal orientation by clamping the substrate W from a periphery. Likewise, the second chuck 12 is arranged to hold a substrate W in the horizontal orientation by clamping the substrate W from the periphery. As shown in FIG. 3, a position of holding of the substrate W by the first chuck 9 and a position of holding of the substrate W by the second chuck 12 overlap in a plan view. The second chuck 12 is merely disposed at a different height from the first chuck 9 and has an arrangement in common with the first chuck 9. That is, the first upper guides 7 and the first lower guides 8 correspond respectively to the second upper guides 10 and the second lower guides 11. Thus, the first chuck 9 shall mainly be described in the following description.

As shown in FIG. 2, the first upper guides 7 and the first lower guides 8 are disposed so as to be aligned with a peripheral edge portion of a single substrate W. The two first upper guides 7 face each other in the facing direction D2 and the two first lower guides 8 face each other in the facing direction D2 at a height lower than that of the first upper guides 7. The two first upper guides 7 are disposed respectively above the two first lower guides 8. The first upper guides 7 and the first lower guides 8 have wedge-shaped front surfaces and back surfaces, and a first upper guide 7 and a first lower guide 8 that are aligned vertically form a V-shaped holding groove that opens toward a center of the substrate W. The peripheral edge portion of the substrate W is disposed inside the holding groove. Thus, each of the first upper guide 7 and the first lower guide 8 has a shape that is vertically inverse to the shape of the other.

As shown in FIG. 2, the first upper guides 7 have upper inclined portions 22 (first upper inclined portions, second upper inclined portions), inclined obliquely upward toward a vertical reference line L2 passing through the center of the substrate W, at reference line L2 sides. The first lower guides 8 have lower inclined portions 23 (first lower inclined portions, second lower inclined portions), inclined obliquely downward toward the reference line L2, at reference line L2 sides. As shown in FIG. 4, when the upper inclined portions 22 and the lower inclined portions 23 are viewed in the facing direction D2 from the substrate W side, each upper inclined portion 22 has an inverted trapezoidal shape and each lower inclined portion 23 has a trapezoidal shape. The upper inclined portions 22 are faced downward and the lower inclined portions 23 are faced upward. As shown in FIG. 2, the upper inclined portions 22 and the lower inclined portions 23 are arranged to contact the peripheral edge portion of the substrate W. The substrate W is supported in the horizontal orientation by point contacts of the respective lower inclined portions 23 with the peripheral edge portion of the substrate W. Further, the substrate W is guided by the inclinations of the plurality of lower inclined portions 23 so that the center of the substrate W is positioned at a middle of the two first lower guides 8. Yet further, the substrate W is restricted in movement in the horizontal direction and the vertical direction by the point contacts of the respective lower inclined portions 23 with the peripheral edge portion of the substrate W and point contacts of the respective upper inclined portions 22 with the peripheral edge portion of the substrate W. Accordingly, the substrate W is clamped.

As shown in an enlarged manner in FIG. 5, the first upper guide 7 and the first lower guide 8 may further have facing portions 24 that extend upward or downward from outer ends of the upper inclined portion 22 and the lower inclined portion 23 and face a peripheral end surface of the substrate W. In this case, movement of the substrate W in the horizontal direction is restricted by contacts of the facing portions 24 with the peripheral end surface of the substrate W, and opening up of the first upper guide 7 and the first lower guide 8 vertically due to the peripheral edge portion of the substrate W becoming caught between the first upper guide 7 and the first lower guide 8 can be suppressed or prevented. Likewise, opening up of the second upper guide 10 and the second lower guide 11 vertically can be suppressed or prevented.

As shown in FIG. 2 and FIG. 4, each of the guides 7, 8, 10, and 11 is coupled via a supporting bracket 25 to one of the cylinders 13. The cylinders 13 are provided respectively for the guides 7, 8, 10, and 11. Each cylinder 13 is held by one of the holding boxes 14. Each of the guides 7, 8, 10, and 11 is thus held by one of the holding boxes 14 via the supporting bracket 25 and the cylinder 13. The guides 7, 8, 10, and 11, supporting brackets 25, and cylinders 13 that are held by the same holding box 14 rotate integrally around the inversion axis L1 together with the holding box 14.

When the electric motor 18 rotates one of the rotating shafts 15 in a state where at least one of either of the first chuck 9 and the second chuck 12 is clamping a substrate W, a driving force of the electric motor 18 is transmitted from one holding box 14 to the other holding box 14 via the substrate W. All of the guides 7, 8, 10, and 11, holding boxes 14, and rotating shafts 15 thereby rotate around the inversion axis L1. Thus, when the electric motor 18 rotates one rotating shaft 15 by 180 degrees in the state where at least one of either of the first chuck 9 and the second chuck 12 is clamping a substrate W, the substrate W clamped by at least one of either of the first chuck 9 and the second chuck 12 is inverted so that a position of a top surface and a position of a rear surface are interchanged.

As shown in FIG. 4, each holding box 14 houses four cylinders 13. The cylinder 13 coupled to the first upper guide 7 is a first upper cylinder 13a (first upper guide moving unit), and the cylinder 13 coupled to the first lower guide 8 is a first lower cylinder 13b (first lower guide moving unit). Also, the cylinder 13 coupled to the second upper guide 10 is a second upper cylinder 13c (second upper guide moving unit), and the cylinders 13 coupled to the second lower guide 11 is a second lower cylinder 13d (second lower guide moving unit).

As shown in FIG. 4, the first upper cylinder 13a and the first lower cylinder 13b are disposed between two side walls 26. The first upper cylinder 13a and the first lower cylinder 13b are mounted on an upper wall 28 of the holding box 14 at respective sides of a partition wall 27 that partitions an interior of the holding box 14. Likewise, the second upper cylinder 13c and the second lower cylinder 13d are disposed between the two side walls 26. The second upper cylinder 13c and the second lower cylinder 13d are mounted on a lower wall 29 of the holding box 14 at respective sides of the partition wall 27. The first upper cylinder 13a and the first lower cylinder 13b are disposed respectively above the second upper cylinder 13c and the second lower cylinder 13d.

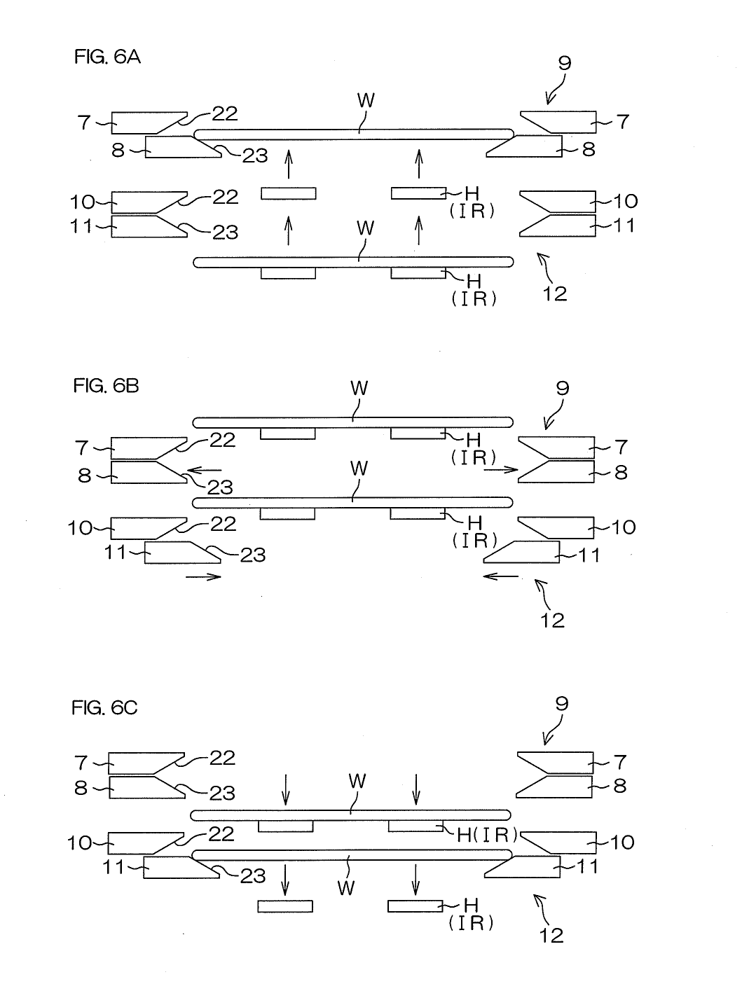

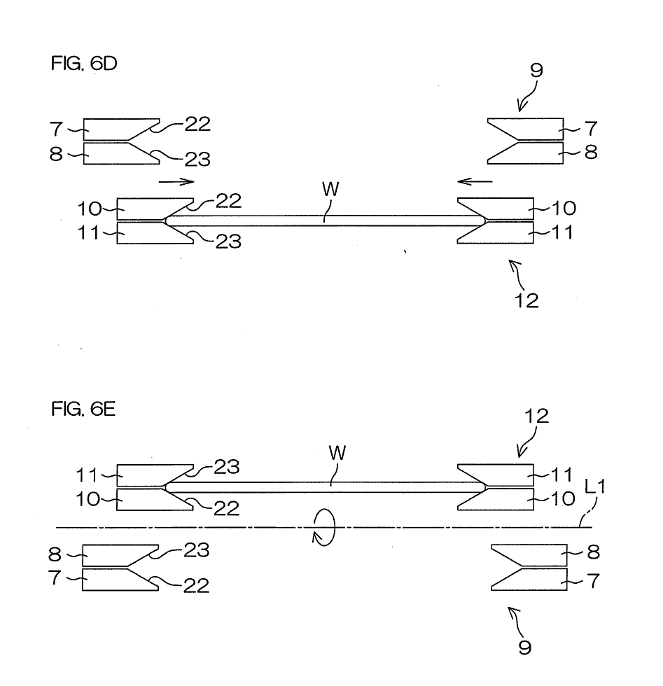

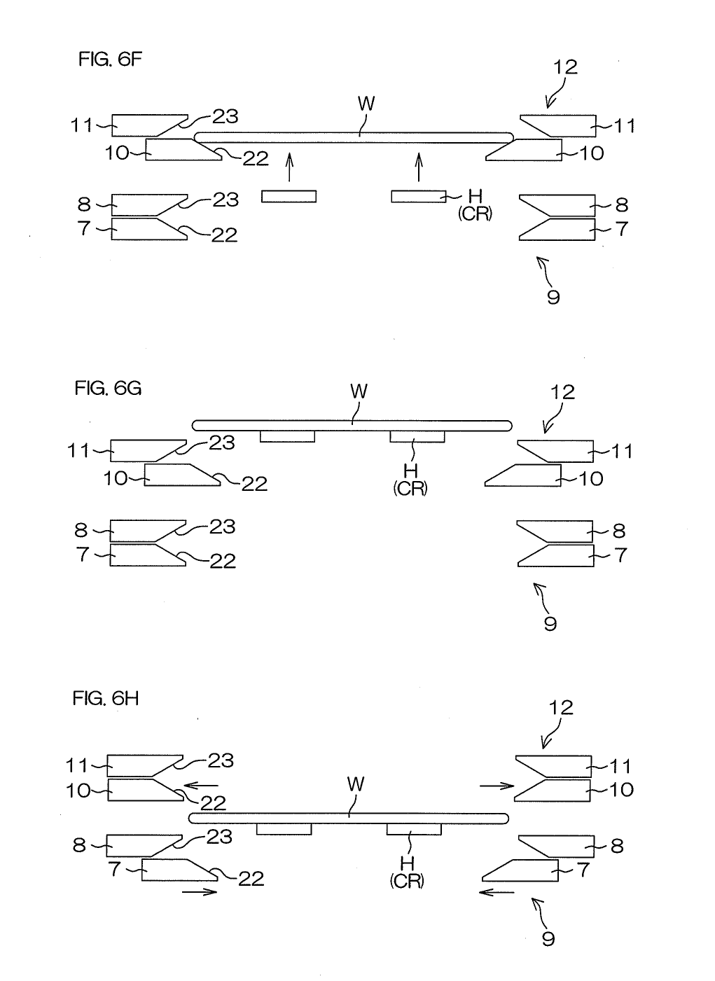

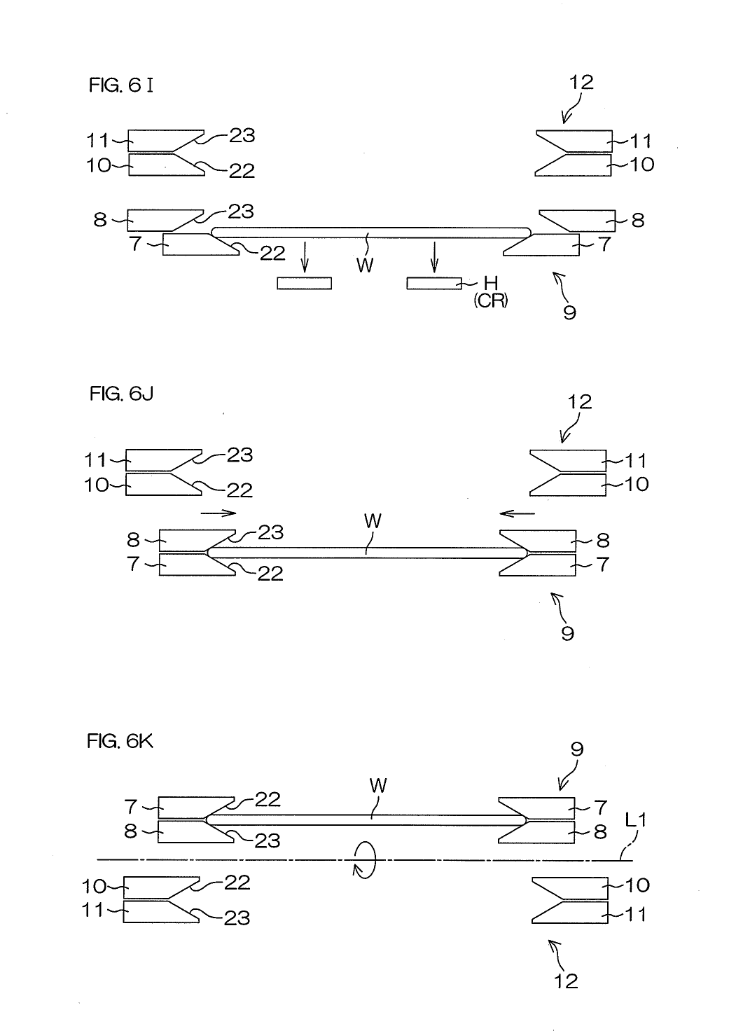

The cylinders 13 move the corresponding guides 7, 8, 10, and 11 in the facing direction D2 between contacting positions (positions shown in FIG. 2 and FIG. 3) at which the guides 7, 8, 10, and 11 contact the peripheral edge portion of a substrate W and withdrawn positions (see, for example, FIG. 6) at which the guides 7, 8, 10, and 11 are separated from the peripheral edge portion of the substrate W. At the contacting positions, inner ends (ends at the reference line L2 side) of the guides 7, 8, 10, and 11 are positioned further inward than (to the reference line L2 side of) the peripheral end surface of the substrate W. At the withdrawn positions, the inner ends of the guides 7, 8, 10, and 11 are positioned further outward than the peripheral end surface of the substrate W. As shown in FIG. 2, to each supporting bracket 25 is mounted a positioning block 30 that moves together with the supporting bracket 25. Also, stoppers 31 that face the positioning blocks 30 in the facing direction D2 are mounted on the holding box 14. The guides 7, 8, 10, and 11 are positioned with high precision at the contacting positions by contacts of the positioning blocks 30 with the stoppers 31.

By means of the plurality of cylinders 13, the controller 4 changes an interval between two guides facing each other in the facing direction independently of intervals between other guides. In a state where the first upper guides 7 are positioned at the withdrawn positions and the first lower guides 8 are positioned at the contacting positions (see FIG. 6A), the controller 4 makes one of the hands H place a substrate W on the lower inclined portions 23 of the two first lower guides 8. The substrate W is thereby transferred onto the two first lower guides 8. Also, in the state where the first upper guides 7 are positioned at the withdrawn positions and the first lower guides 8 are positioned at the contacting positions, the controller 4 makes one of the hands H lift up the substrate W supported by the two first lower guides 8 (see FIG. 6B). The substrate W is thereby received from the two first lower guides 8. Further, in the state where the substrate W is supported by the two first lower guides 8, the controller 4 moves the two first upper guides 7 to the contacting positions and makes the respective first upper guides 7 contact the peripheral edge portion of the substrate W. The substrate W is thereby clamped. In this state, the controller 4 makes the electric motor 18 (output shaft of the electric motor 18) rotate by 180 degrees around the inversion axis L1 to invert the substrate W.

When the controller 4 makes the electric motor 18 rotate by 180 degrees, a vertical relationship of the first chuck 9 and the second chuck 12 is interchanged (see FIG. 6E) because the inversion axis L1 is provided at a height between the first chuck 9 and the second chuck 12. Further, a vertical relationship of the first upper guides 7 and first lower guides 8 is interchanged, and a vertical relationship of the second upper guides 10 and second lower guides 11 is interchanged. That is, by means of the electric motor 18, the controller 4 moves the guides 7, 8, 10, and 11 between upwardly facing positions, at which the upper inclined portions 22 and the lower inclined portions 23 are faced upward, and downwardly facing positions. FIG. 2 and FIG. 3 show a state where the first upper guides 7 and the second upper guides 10 are positioned at the downwardly facing positions and the first lower guides 8 and the second lower guides 11 are positioned at the upwardly facing positions.

When the first upper guides 7 move to the upwardly facing positions, the upper inclined portions 22 are faced upward (see FIG. 6E) and thus the two first upper guides 7 are put in orientations enabling supporting of a substrate W by the two upper inclined portions 22. In the state where the two first upper guides 7 are positioned at the upwardly facing positions, the controller 4 makes conveying-in of a substrate W onto the two first upper guides 7 and conveying-out of a substrate W from the two first upper guides 7 be performed in the same manner as in the transfer of a substrate W between the two first lower guides 8 and a hand H. Likewise, in the state where the two second upper guides 10 are positioned at the upwardly facing positions, the controller 4 makes conveying-in of a substrate W onto the two second upper guides 10 and conveying-out of a substrate W from the two second upper guides 10 be performed by the indexer robot IR or the center robot CR.

FIG. 6A to FIG. 6K are schematic views of an example of operations performed during inversion of a substrate W by the inverting path 5. In the following description, the example of operations performed when a processed substrate W is conveyed out from the first chuck 9, an unprocessed substrate W is conveyed into the second chuck 12, and thereafter the substrate W held by the second chuck 12 is inverted shall be described (FIGS. 6A to 6E). Further, operations performed when the unprocessed substrate W is conveyed out by the center robot CR, another processed substrate W is conveyed into the first chuck 9, and the processed substrate W is inverted shall be described (FIGS. 6F to 6K).

FIG. 6A shows a state where the first upper guides 7 and the second upper guides 10 are positioned at the downwardly facing positions and the first lower guides 8 and the second lower guides 11 are positioned at the upwardly facing positions. Further, FIG. 6A shows a state where the first upper guides 7, the second upper guides 10, and the second lower guides 11 are positioned at the withdrawn positions and the first lower guides 8 are positioned at the contacting positions. A processed substrate W is supported by the two first lower guides 8. In this state, the controller 4 makes the upper side hand H of the indexer robot IR move horizontally to make the upper side hand H enter below the substrate W supported by the two first lower guides 8. Further, the controller 4 makes the lower side hand H of the indexer robot IR that supports an unprocessed substrate W move horizontally to make the lower side hand H enter below the second lower guides 11.

Thereafter, in the state where the upper side hand H is positioned below the substrate W supported by the two first lower guides 8, the controller 4 makes the two hands H rise as shown in FIG. 6A. The substrate W supported by the two first lower guides 8 is thereby received by the upper side hand H as shown in FIG. 6B. Also, during this process, the second upper guides 10 and the second lower guides 11 are positioned at the withdrawn positions, and thus as shown in FIG. 6A, the substrate W held by the lower side hand H passes between the two second upper guides 10 and between the two lower guides 11 and moves above the two second lower guides 11.

Thereafter, in the state where the substrate W held by the lower side hand H is positioned at a height between the first lower guides 8 and the second lower guides 11, the controller 4 makes the two first lower guides 8 move to the withdrawn positions and makes the two second lower guides 11 move to the contacting positions as shown in FIG. 6B. Just the second lower guides 11 are thereby positioned at the contacting positions. In this state, the controller 4 makes the two hands H descend until the lower side hand H moves below the second lower guides 11 as shown in FIG. 6C. The substrate W held by the lower side hand H is thereby placed on the two second lower guides 11 and the unprocessed substrate W is transferred to the second chuck 12 as shown in FIG. 6C. Also, the first upper guides 7 and the first lower guides 8 are positioned at the withdrawn positions and thus the substrate W held by the upper side hand H passes between the two first upper guides 7 and between the two first lower guides 8. After the unprocessed substrate W has been transferred to the second chuck 12, the controller 4 makes the two hands H of the indexer robot IR move horizontally and be withdrawn from the inverting path 5. The processed substrate W is thereby conveyed out from the first chuck 9 and the unprocessed substrate W is conveyed into the second chuck 12.

Thereafter, in the state where the substrate W is supported by the two second lower guides 11, the controller 4 makes the two second upper guides 10 move to the contacting positions as shown in FIG. 6D. The respective second upper guides 10 thereby contact the peripheral edge portion of the substrate W and the substrate W is held by the second chuck 12. In the state where the substrate W is held by the second chuck 12, the controller 4 rotates all of the guides 7, 8, 10, and 11 by 180 degrees around the inversion axis L1 as shown in FIG. 6E. The vertical relationship of the first chuck 9 and the second chuck 12 is thereby interchanged and the substrate W held by the second chuck 12 is inverted. Further, the first upper guides 7 and the second upper guides 10 move to the upwardly facing positions and the first lower guides 8 and the second lower guides 11 move to the downwardly facing positions.

After the substrate W has been inverted, the controller 4 moves the second lower guides 11 to the withdrawn positions as shown in FIG. 6F. Thereafter, the controller 4 makes a hand H of the center robot CR enter below the substrate W supported by the second upper guides 10 at the upwardly facing positions. The controller 4 makes the hand H rise to lift up and convey out the substrate W from the two second upper guides 10 as shown in FIG. 6G. The unprocessed substrate W that has been conveyed out from the two second upper guides 10 is then conveyed into the processing unit 3 by the center robot CR and is processed by the processing unit 3.

The processed substrate W, with which the processing at the processing unit 3 has ended, is conveyed out by the center robot CR. As shown in FIG. 6H, the controller 4 positions the first lower guides 8, the second upper guides 10, and the second lower guides 11 at the withdrawn positions and positions the first upper guides 7 at the contacting positions. In this state, the controller 4 makes the hand H of the center robot CR that holds the processed substrate W enter to a position higher than a substrate holding height of the first upper guides 7.

Thereafter, as shown in FIG. 6I, the controller 4 makes the hand H of the center robot CR descend. In this process, the processed substrate W is transferred from the hand H to the first upper guides 7. Thereafter, the controller 4 makes the hand H of the center robot CR withdraw from a space below the substrate W.

Thereafter, as shown in FIG. 6J, the controller 4 moves the first lower guides 8 to the contacting positions. A state in which the processed substrate W is held by the first chuck 9 is thereby entered.

Thereafter, in the state where the substrate W is held by the first chuck 9, the controller 4 makes all of the guides 7, 8, 10, and 11 rotate by 180 degrees around the inversion axis L1 as shown in FIG. 6K. The vertical relationship of the first chuck 9 and the second chuck 12 is thereby interchanged and the substrate W held by the first chuck 9 is inverted. Further, the first upper guides 7 and the second upper guides 10 move to the downwardly facing positions and the first lower guides 8 and the second lower guides 11 move to the upwardly facing positions.

Thereafter, the controller 4 controls the indexer robot IR to perform the conveying-out of the processed substrate W from the first chuck 9 and the conveying-in of an unprocessed substrate W to the second chuck 12 as shown in FIG. 6A.

As described above, with the first preferred embodiment, the inverting path 5 moves the guides 7, 8, 10, and 11 horizontally to clamp the substrate W. Spaces for movement of the guides 7, 8, 10, and 11 thus do not have to be provided above and below the guides 7, 8, 10, and 11. The inverting path 5 can thus be reduced in height in comparison to an arrangement in which the guides are moved vertically to perform clamping. Enlargement of the inverting path 5 can thereby be suppressed or prevented. Enlargement of the substrate processing apparatus 1 can thus be suppressed or prevented.

Further, an interval (interval in the vertical direction) between the first chuck 9 and the second chuck 12 can be narrowed because spaces for movement of the guides 7, 8, 10, and 11 do not have to be provided above and below the guides 7, 8, 10, and 11. The interval between the first chuck 9 and the second chuck 12 can thus be matched to a pitch (interval in the vertical direction) of two hands H that are aligned vertically. Two substrates W can thus be conveyed into the two chucks 9 and 12 from the two hands H at the same time and two substrates W can be conveyed out from the two chucks 9 and 12 at the same time. Time required for transfer of substrate W between the substrate conveying robots IR and CR and the inverting path 5 can thereby be shortened.

Although with the operation example described above, an example where transfers of the unprocessed substrate W and the processed substrate W between the center robot CR and the inverting path 5 are performed successively has been described, transfers of the unprocessed substrate W and the processed substrate W may be performed at the same time by performing the same operations as those of the transfers of the substrates W between the indexer robot IR and the inverting path 5.

### Second Preferred Embodiment

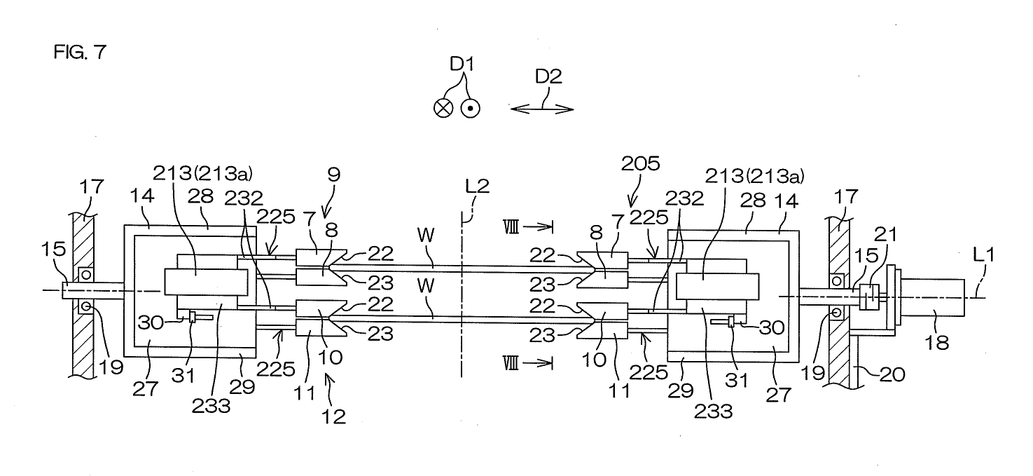

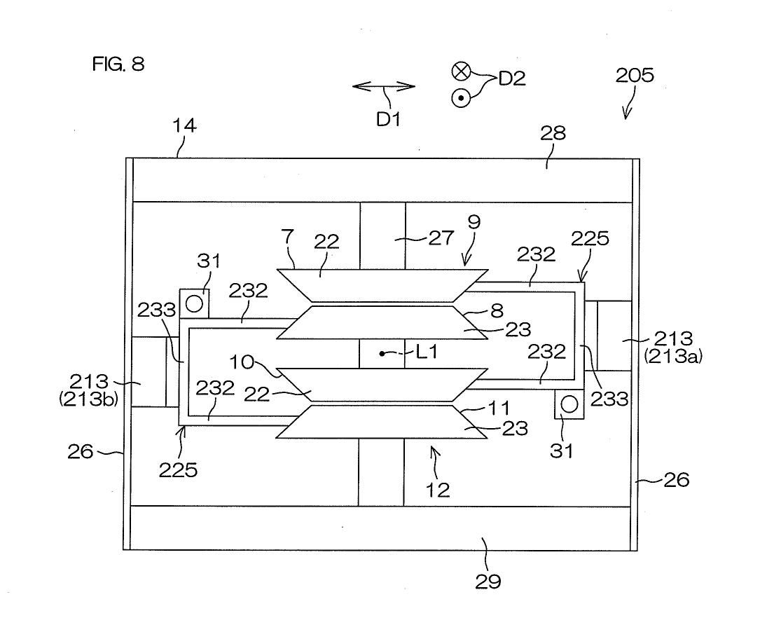

FIG. 7 is a schematic front view for describing an internal arrangement of an inverting path 205 according to a second preferred embodiment of the present invention. FIG. 8 is a schematic view of the inverting path 205 as viewed from a direction of an arrow VIII shown in FIG. 7. In FIG. 7 and FIG. 8, component portions corresponding to portions indicated in FIG. 1 to FIG. 6 described above are provided with the same reference symbols as in FIG. 1, etc., and description thereof shall be omitted.

A principal point of difference of the second preferred embodiment with respect to the first preferred embodiment is that a plurality of guides are driven by a cylinder in common.

Specifically, in place of the supporting brackets 25 according to the first preferred embodiment, the inverting path 205 (substrate inverting apparatus) includes a plurality (for example, 4) supporting brackets 225. Each supporting bracket 225 includes two guide supporting portions 232 that are spaced apart by an interval in the vertical direction and a coupling portion 233 coupled to the two guide supporting portions 232. The first upper guide 7 and the second upper guide 10 are mounted respectively on the two guide supporting portions 232 of a supporting bracket 225 in common. Likewise, the first lower guide 8 and the second lower guide 11 are mounted respectively on the two guide supporting portions 232 of a supporting bracket 225 in common. Each coupling portion 233 is coupled to a cylinder 213 (guide moving mechanism). The first upper guide 7 and the second upper guide 10 are thus coupled to a cylinder 213 via the supporting bracket 225 in common, and the first lower guide 8 and the second lower guide 11 are coupled to a cylinder 213 via the supporting bracket 225 in common. The cylinder 213 coupled to the first upper guide 7 and the second upper guide 10 is an upper cylinder 213a (upper guide moving module), and the cylinder 213 coupled to the first lower guide 8 and the second lower guide 11 is a lower cylinder 213b (lower guide moving module).

The cylinders 213 are mounted on the holding box 14. Two cylinders 213 are mounted on each of the two holding boxes 14. Each cylinder 213 moves the corresponding supporting bracket 225 in the facing direction D2 to simultaneously move the two guides (for example, the first upper guide 7 and the second upper guide 10) coupled to the supporting bracket 225. The first upper guide 7 and the second upper guide 10 thereby move together in the facing direction D2, and the first lower guide 8 and the second lower guide 11 move together in the facing direction D2.

As described above, with the second preferred embodiment, the upper cylinder 213a moves the first upper guide 7 and the second upper guide 10 in the facing direction D2, and the lower cylinder 213b moves the first lower guide 8 and the second lower guide 11 in the facing direction D2. That is, a single cylinder 213 moves a plurality of guides in the facing direction D2. Thus, in comparison to an arrangement where the cylinder 13 is provided for each of the guides 7, 8, 10, and 11 as in the first preferred embodiment, the cylinders 213 can be reduced in number. Enlargement of the inverting path 205 can thereby be suppressed or prevented.

### Third Preferred Embodiment

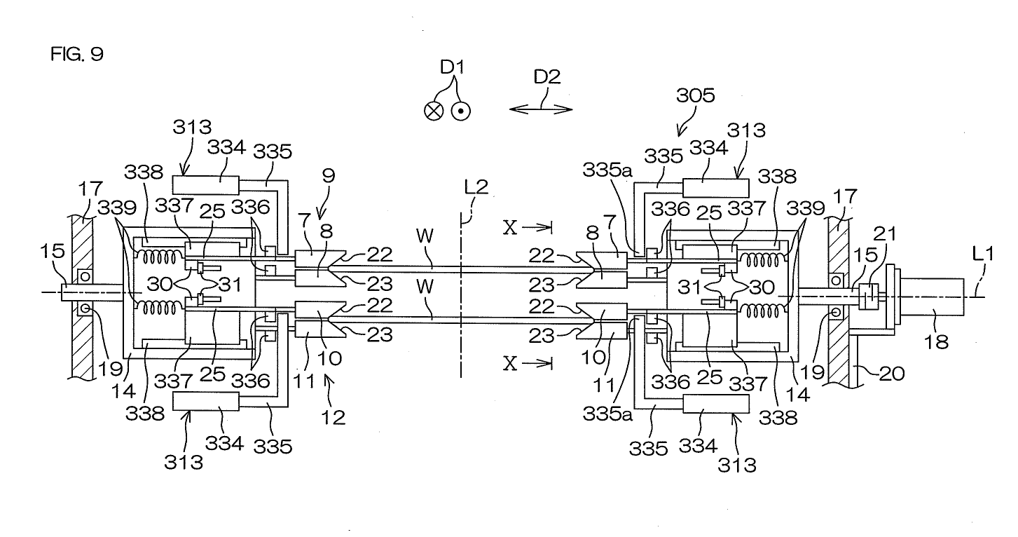

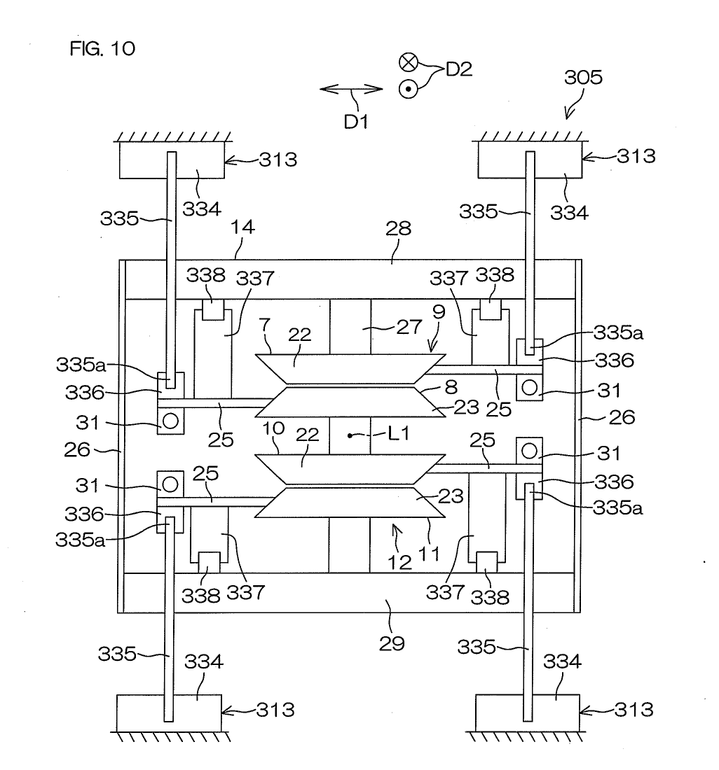

FIG. 9 is a schematic front view for describing an internal arrangement of an inverting path 305 according to a third preferred embodiment of the present invention. FIG. 10 is a schematic view of the inverting path 305 as viewed from a direction of an arrow X shown in FIG. 9. In FIG. 9 and FIG. 10, component portions corresponding to portions indicated in FIG. 1 to FIG. 8 described above are provided with the same reference symbols as in FIG. 1, etc., and description thereof shall be omitted.

A principal point of difference of the third preferred embodiment with respect to the first preferred embodiment is that cylinders are not held by a holding box, and guides and the holding box rotate around the inversion axis relative to the cylinders.

Specifically, the inverting path 305 (substrate inverting apparatus) includes a plurality of cylinders 313 (guide moving mechanisms) provided according to each of the guides 7, 8, 10, and 11. Each cylinder 313 is disposed outside the holding box 14 and fixed to the supporting plate 17. The cylinder 313 includes a main body 334 fixed to the supporting plate 17 and an arm 335 that moves in the facing direction D2 with respect to the main body 334. The main body 334 is disposed in a periphery of a space through which the holding box 14 passes when it rotates around the inversion axis L1. The arm 335 is disposed in a periphery of a space through which the holding box 14 and the supporting brackets 25 pass when these rotate around the inversion axis L1. A tip portion 335a of the arm 335 faces a driving force transmitting block 336, mounted on the supporting bracket 25, in the facing direction D2. The tip portion 335a of the arm 335 is disposed at an inner side (reference line L2 side) of the driving force transmitting block 336. By moving the arm 335 to an outer side, the cylinder 313 makes the tip portion 335a of the arm 335 contact the driving force transmitting block 336. The driving force of the cylinder 313 is thereby transmitted to the supporting bracket 25 via the driving force transmitting block 336.

Each supporting bracket 25 is held by the holding box 14 via a sliding block 337 mounted on the supporting bracket 25 and a linear guide 338 mounted on the holding box 14. The linear guide 338 extends in the facing direction D2. The sliding block 337 slides along the linear guide 338. The supporting bracket 25 is thus held by the holding box 14 in a manner enabling movement in the facing direction D2.

As shown in FIG. 9, the inversion path 305 further includes a plurality of elastic members 339 (for example, compression springs) disposed inside the holding box 14. Each elastic member 339 is mounted on the supporting bracket 25 and the holding box 14 and urges the supporting bracket 25 inward (in the direction toward the reference line L2). The positioning block 30 is pressed against the stopper 31 by a restoring force of the elastic member 339. The guides 7, 8, 10, and 11 are thereby held at the contacting positions.

When the supporting brackets 25 are pressed outward by the cylinders 313 moving the arms 335 outward, the elastic members 339 deform elastically and the guides 7, 8, 10, and 11 move toward the withdrawn positions. Also, when the cylinders 313 move the arms 335 inward in the state where the guides 7, 8, 10, and 11 are positioned at the withdrawn positions, the supporting brackets 25 move inward by the restoring force of the elastic member 339 and the guides 7, 8, 10, and 11 return to the contacting positions. The guides 7, 8, 10, and 11 are thereby moved between the contacting positions and the withdrawn positions.

As shown in FIG. 10, two cylinders 313 are disposed above each holding box 14. Also, two cylinders 313 are disposed below the holding box 14. The two cylinders 313 at the upper side are disposed respectively above the two cylinders 313 at the lower side. If the cylinder 313 at the upper right, the cylinder 313 at the lower right, the cylinder 313 at upper left, and the cylinder 313 at the lower left in FIG. 10 are respectively defined as the upper right fixed cylinder 313, the lower right fixed cylinder 313, the upper left fixed cylinder 313, and the lower left fixed cylinder 313, then, for example, in the state where the first upper guide 7 is positioned above the second upper guide 10 (state shown in FIG. 10), the first upper guide 7 is driven by the upper right fixed cylinder 313 and the second upper guide 10 is driven by the lower right fixed cylinder 313. Also, the first lower guide 8 is driven by the upper left fixed cylinder 313 and the second lower guide 11 is driven by the lower left fixed cylinder 313.

On the other hand, when the electric motor 18 rotates the holding box 14 by 180 degrees around the inversion axis L1, the second upper guide 10 moves to a position above the first upper guide 7. At the same time, the power transmitting block 336 corresponding to the first upper guide 7 moves from the position facing the tip portion 335a of the arm 335 of the upper right fixed cylinder 313 to a position of facing the tip portion 335a of the arm 335 of the lower left fixed cylinder 313. Further, the power transmitting block 336 corresponding to the second upper guide 10 moves from the position facing the tip portion 335a of the arm 335 of the lower right fixed cylinder 313 to a position of facing the tip portion 335a of the arm 335 of the upper left fixed cylinder 313. Thus, after the holding box 14 has been rotated by 180 degrees, the second upper guide 10 is driven by the upper left fixed cylinder 313 and the first upper guide 7 is driven by the lower left fixed cylinder 313. Further, after the holding box 14 has rotated by 180 degrees, the second lower guide 11 is driven by the upper right fixed cylinder 313 and the first lower guide 8 is driven by the lower right fixed cylinder 313.

When the electric motor 18 rotates the holding box 14 further by 180 degrees, the vertical relationship of the first upper guide 7 and the second upper guide 10 is interchanged again and the first upper guide 7 is driven by the upper right fixed cylinder 313 and the second upper guide 10 is driven by the lower right fixed cylinder 313. Likewise, the first lower guide 8 is driven by the upper left fixed cylinder 313 and the second lower guide 11 is driven by the lower left fixed cylinder 313. The cylinders 313 and the holding box 14 thus rotate relative to each other around the inversion axis L1 and thus when the electric motor 18 rotates the holding box 14 around the inversion axis L1, the cylinders 313 that drive the guides 7, 8, 10, and 11 are interchanged at every 180 degrees.

As described above, with the third preferred embodiment, the cylinders 313 are rotatable around the inversion axis L1 relative to the guides 7, 8, 10, and 11 and thus the electric motor 18 does not have to rotate the cylinders 313 around the inversion axis L1 when inverting the substrate W. Amass of a rotating body rotated by the electric motor 18 can thus be reduced. A compact motor of low output can thus be used as the electric motor 18. Enlargement of the inverting path 305 can thereby be suppressed or prevented.

### Fourth Preferred Embodiment

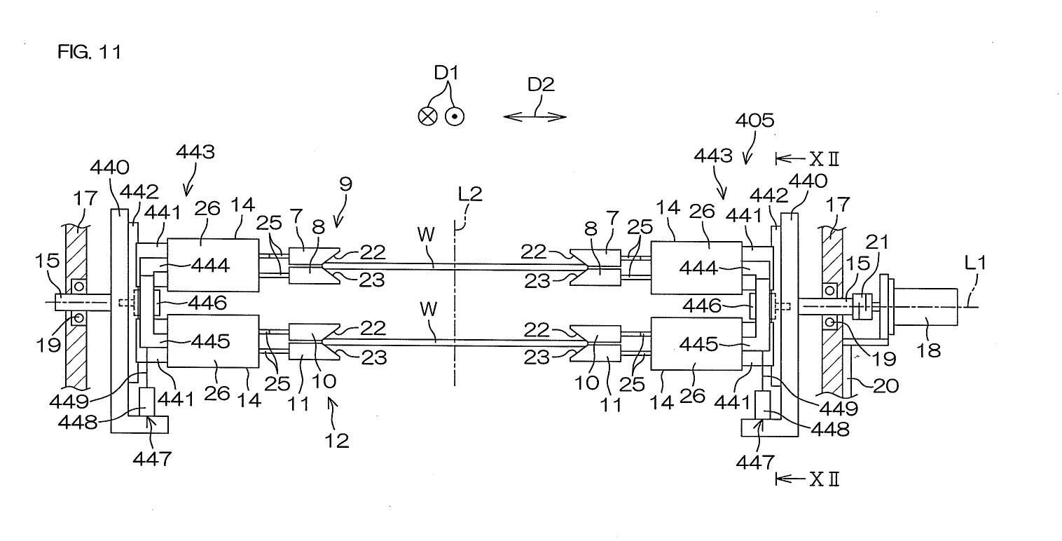

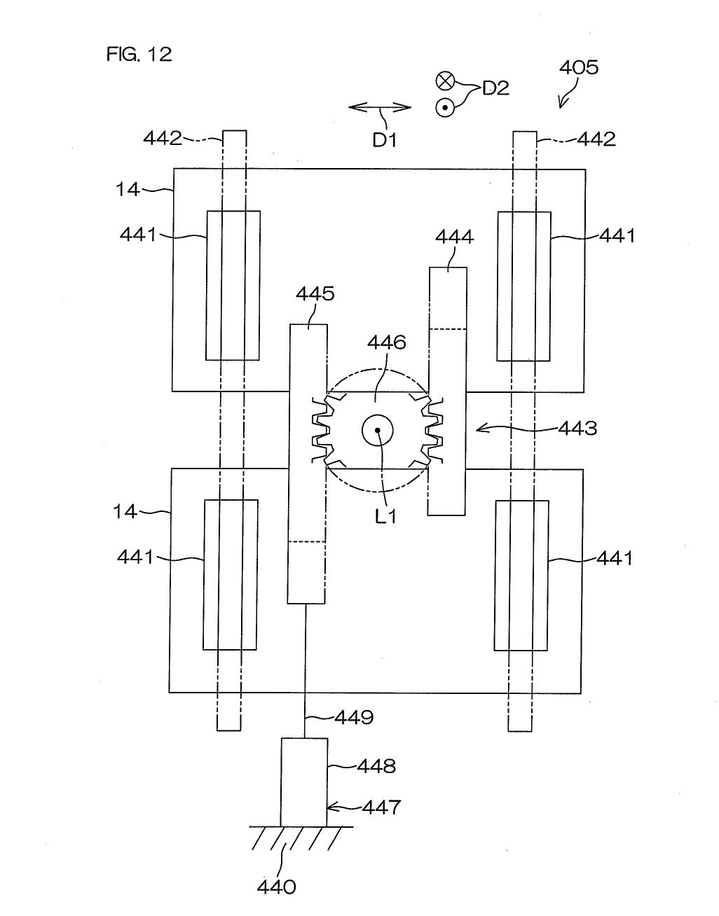

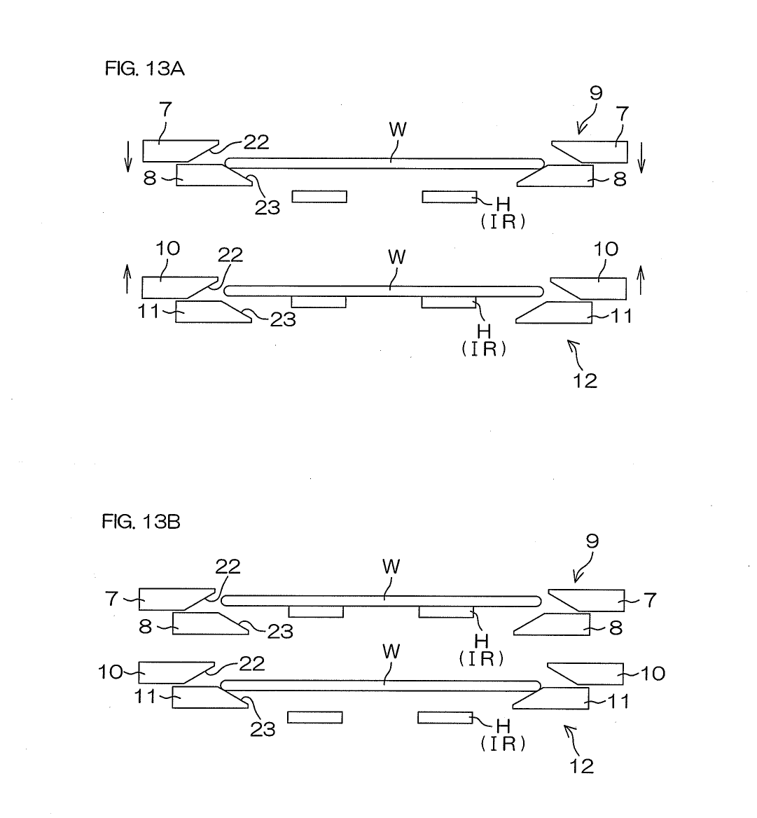

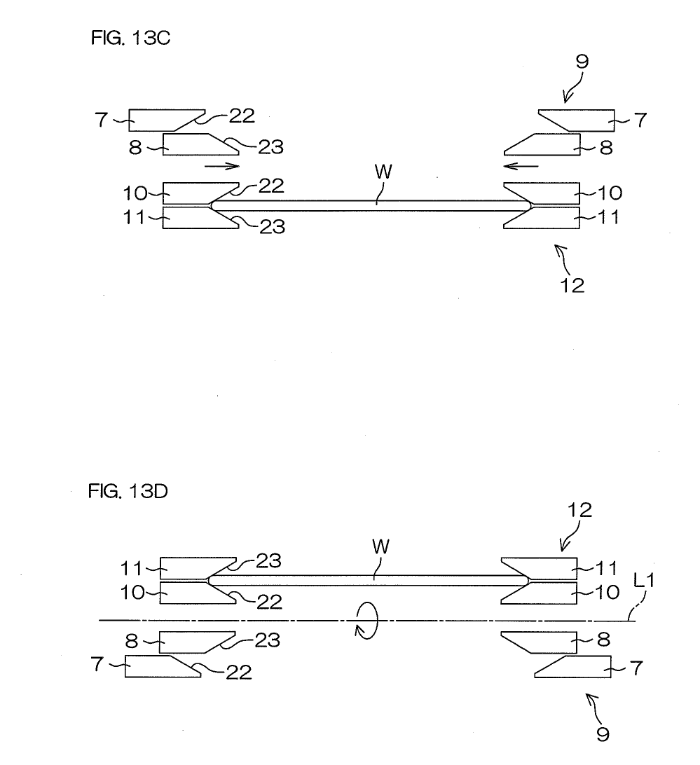

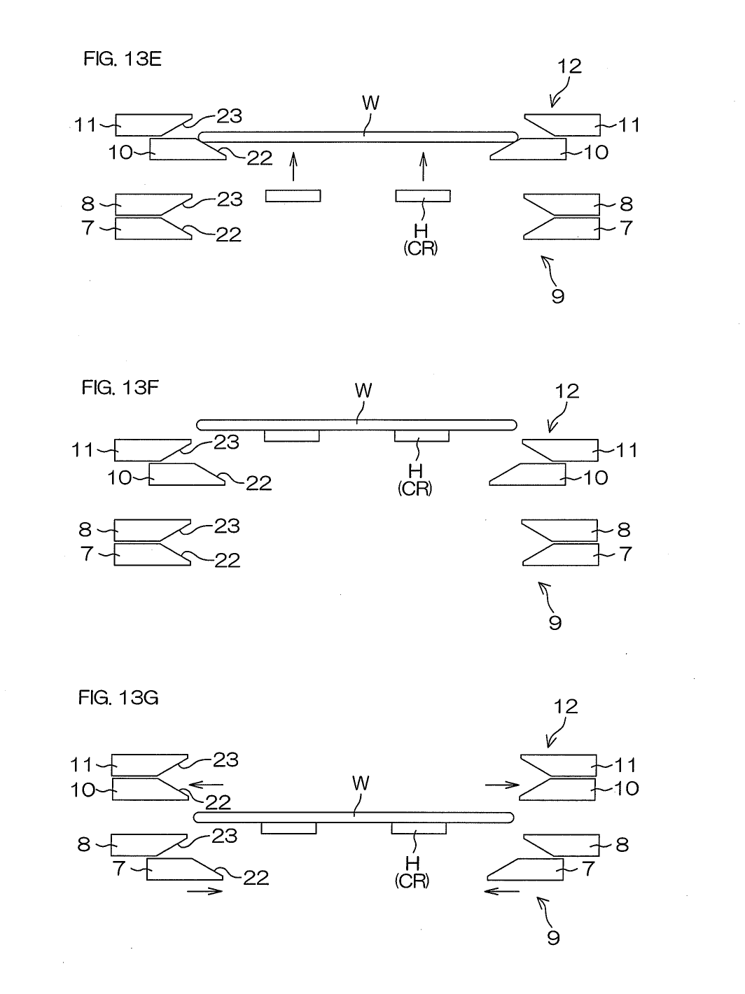

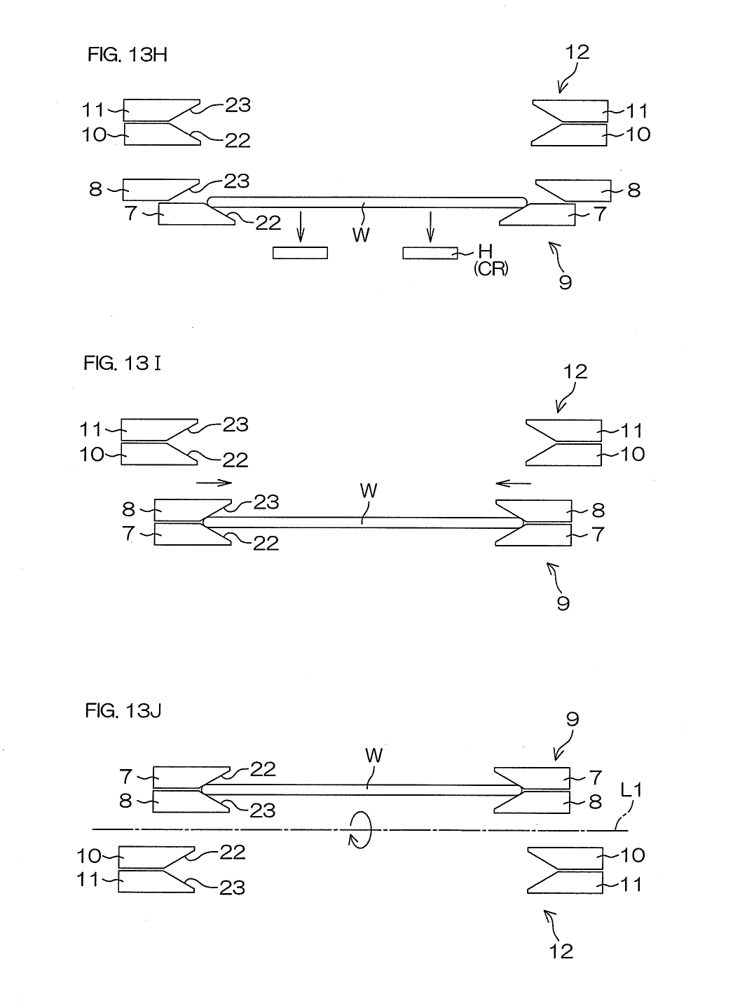

FIG. 11 is a schematic front view for describing an arrangement of an inverting path 405 according to a fourth preferred embodiment of the present invention. FIG. 12 is a schematic view of the inverting path 405 as viewed from a direction of an arrow XII shown in FIG. 11. In FIG. 11, FIG. 12, and FIG. 13A to FIG. 13D, component portions corresponding to portions indicated in FIG. 1 to FIG. 10 described above are provided with the same reference symbols as in FIG. 1, etc., and description thereof shall be omitted.

A principal point of difference of the fourth preferred embodiment with respect to the first preferred embodiment is that guide raising/lowering units that raise and lower the first chuck and the second chuck to change an interval between the first chuck and the second chuck are provided.

Specifically, the inverting path 405 (substrate inverting apparatus) includes four holding boxes 14. As shown in FIG. 11, the four holding boxes 14 are disposed between two supporting plates 17. Two of the holding boxes 14 are disposed at the side of one of the supporting plates 17 and the remaining two holding boxes 14 are disposed at the side of the other supporting plate 17. The two holding boxes 14 disposed at the side of one of the supporting plate 17 are aligned vertically, and the two holding boxes 14 disposed at the side of the other supporting plate 17 are aligned vertically. The two holding boxes 14 disposed at the side of one of the supporting plate 17 respectively face the two holding boxes 14 disposed at the side of the other supporting plate 17 in the facing direction D2.

The two holding boxes 14 at the upper side correspond to the first chuck 9 and hold the first upper guides 7 and the first lower guides 8 via the supporting brackets 25. Likewise, the two holding boxes 14 at the lower side correspond to the second chuck 12 and hold the second upper guides 10 and the second lower guides 11 via the supporting brackets 25. Each holding box 14 thus holds two guides (guides 7 and 8 or guides 10 and 11). Although not illustrated, two cylinders 13 (see FIG. 2) coupled respectively to the two guides are housed in each holding box 14.

As shown in FIG. 11, the inverting path 405 further includes two holding plates 440 each holding two vertically aligned holding boxes 14 in a manner enabling raising and lowering. The two holding plates 440 face each other in the facing direction D2 between the two supporting plates 17. The four holding boxes 14 are disposed between the two holding plates 440. Each holding box 14 is held by the holding plate 440 via a sliding block 441 mounted on the holding box 14 and a linear guide 442 mounted on the holding plate 440. The linear guide 442 extends in the vertical direction. The holding box 14 is thus held by the holding plate 440 in a manner enabling movement in the vertical direction. Also, the two rotating shafts 15 are coupled respectively to the two holding plates 440. The two rotating shafts 15 respectively extend outward from the two holding plates 440.

The inverting path 405 further includes two guide raising/lowering units 443 (guide raising/lowering units) each of which raises and lowers the two holding boxes 14 held by the holding plate 440 in common to change an interval between the two holding boxes 14. As shown in FIG. 12, each guide raising/lowering unit 443 includes an upper rack 444 coupled to the holding box 14 at the upper side, a lower rack 445 coupled to the holding box 14 at the lower side, a pinion 446 meshed with the upper rack 444 and the lower rack 445, and a raising/lowering actuator 447 coupled to one of either of the upper rack 444 and the lower rack 445. As shown in FIG. 11, the upper rack 444 and the lower rack 445 are disposed between the holding boxes 14 and the holding plate 440. The upper rack 444 and the lower rack 445 extend in the vertical direction. The upper rack 444 and the lower rack 445 are thus disposed in parallel. As shown in FIG. 12, the upper rack 444 extends downward from the upper side holding box 14 and the lower rack 445 extends upward from the lower side holding box 14. A teeth portion of the upper rack 444 and a teeth portion of the lower rack 445 face each other across an interval in the horizontal direction (conveying direction D1). The pinion 446 is disposed between the teeth portion of the upper rack 444 and the teeth portion of the lower rack 445. The pinion 446 is held by the holding plate 440 in a manner enabling rotation around the inversion axis L1.

As shown in FIG. 12, the raising/lowering actuator 447 is held by the holding plate 440. The raising/lowering actuator 447 may be an air cylinder or other pneumatic actuator driven by pneumatic pressure or a solenoid actuator driven by magnetic force. The raising/lowering actuator 447 includes a main body 448 fixed to the holding plate 440 and an arm 449 that rises and descends with respect to the main body 448. The arm 449 is, for example, coupled to a lower end portion of the lower rack 445. When the controller 4 makes the lower rack 445 be raised by the raising/lowering actuator 447, the driving force of the raising/lowering actuator 447 is transmitted via the lower rack 445 and the pinion 446 to the upper rack 444 and the upper rack 444 descends. On the other hand, when the controller 4 makes the lower rack 445 descend by the raising/lowering actuator 447, the upper rack 444 rises. Thus, when the controller 4 makes the lower rack 445 be raised or lowered by the raising/lowering actuator 447, the upper rack 444 and the lower rack 445 move in mutually opposite directions and the interval between the two vertically aligned holding boxes 14 changes. The guide raising/lowering units 443 can thus increase and decrease the interval (interval in the vertical direction) between the first chuck 9 and the second chuck 12.

FIGS. 13A to 13J are schematic views of an example of operations performed during inversion of a substrate W by the inverting path 405. In the following description, the example of operations performed when a processed substrate W is conveyed out from the first chuck 9, an unprocessed substrate W is conveyed into the second chuck 12, and thereafter the substrate W held by the second chuck 12 is inverted shall be described (FIGS. 13A to 13D). Further, operations performed when the unprocessed substrate W is conveyed out by the center robot CR, another processed substrate W is conveyed into the first chuck 9, and the processed substrate W is inverted shall be described (FIGS. 13E to 13J).

FIG. 13A shows a state where the first upper guides 7 and the second upper guides 10 are positioned at the downwardly facing positions and the first lower guides 8 and the second lower guides 11 are positioned at the upwardly facing positions. Further, FIG. 13A shows a state where the first upper guides 7 and the second upper guides 10 are positioned at the withdrawn positions and the first lower guides 8 and the second lower guides 11 are positioned at the contacting positions. A processed substrate W is supported by the two first lower guides 8. In this state, the controller 4 makes the upper side hand H of the indexer robot IR move horizontally to make the upper side hand H enter below the substrate W supported by the two first lower guides 8. Further, the controller 4 makes the lower side hand H of the indexer robot IR that supports an unprocessed substrate W move horizontally to make the lower side hand H enter the inverting path 405 so that the peripheral edge portion of the substrate W is positioned above the second lower guides 11.

Thereafter, the controller 4 controls the guide raising/lowering units 443 to lower the first chuck 9 and raise the second chuck 12 as shown in FIG. 13A. An interval between the first chuck 9 and the second chuck 12 is thereby narrowed. The substrate W supported by the two first lower guides 8 is thereby received by the upper side hand H as shown in FIG. 13B. Further, as shown in FIG. 13B, the substrate W held by the lower side hand H is received by the two second lower guides 11. After the unprocessed substrate W has been transferred to the second chuck 12, the controller 4 makes the two hands H of the indexer robot IR move horizontally and be withdrawn from the inverting path 405. The processed substrate W is thereby conveyed out from the first chuck 9 and the unprocessed substrate W is conveyed into the second chuck 12.

Thereafter, in the state where the substrate W is supported by the two second lower guides 11, the controller 4 moves the two second upper guides 10 to the contacting positions as shown in FIG. 13C. The respective second upper guides 10 thereby contact the peripheral edge portion of the substrate W and the substrate W is held by the second chuck 12. In the state where the substrate W is held by the second chuck 12, the controller 4 rotates all of the guides 7, 8, 10, and 11 by 180 degrees around the inversion axis L1 as shown in FIG. 13D. The vertical relationship of the first chuck 9 and the second chuck 12 is thereby interchanged and the substrate W held by the second chuck 12 is inverted. Further, the first upper guides 7 and the second upper guides 10 move to the upwardly facing positions and the first lower guides 8 and the second lower guides 11 move to the downwardly facing positions.

After the substrate W has been inverted, the controller 4 moves the two second lower guides 11 to the withdrawn positions as shown in FIG. 13E. Thereafter, the controller 4 makes a hand H of the center robot CR enter below the substrate W supported by the second upper guides 10 at the upwardly facing positions. The controller 4 makes the hand H rise to lift up and convey the substrate W out from the two second upper guides 10 as shown in FIG. 13F. The unprocessed substrate W that has been conveyed out from the two second upper guides 10 is then conveyed into the processing unit 3 by the center robot CR and is processed by the processing unit 3.

The processed substrate W, with which the processing at the processing unit 3 has ended, is conveyed out by the center robot CR. As shown in FIG. 13G, the controller 4 positions the first lower guides 8, the second upper guides 10, and the second lower guides 11 at the withdrawn positions and positions the first upper guides 7 at the contacting positions. In this state, the controller 4 makes the hand H of the center robot CR that holds the processed substrate W enter to a position higher than the substrate holding height of the first upper guides 7.

Thereafter, as shown in FIG. 13H, the controller 4 makes the hand H of the center robot CR descend. In this process, the processed substrate W is transferred from the hand H to the first upper guides 7. Thereafter, the controller 4 makes the hand H of the center robot CR withdraw from the space below the substrate W.

Thereafter, as shown in FIG. 13I, the controller 4 moves the first lower guides 8 to the contacting positions. A state in which the processed substrate W is held by the first chuck 9 is thereby entered.

Thereafter, in the state where the substrate W is held by the first chuck 9, the controller 4 makes all of the guides 7, 8, 10, and 11 rotate by 180 degrees around the inversion axis L1 as shown in FIG. 13J. The vertical relationship of the first chuck 9 and the second chuck 12 is thereby interchanged and the substrate W held by the first chuck 9 is inverted. Further, the first upper guides 7 and the second upper guides 10 move to the downwardly facing positions and the first lower guides 8 and the second lower guides 11 move to the upwardly facing positions.

Thereafter, the controller 4 controls the guide raising/lowering units 443 to raise the first chuck 9 and lower the second chuck 12. The interval between the first chuck 9 and the second chuck 12 is thereby widened. Thereafter, the controller 4 controls the indexer robot IR to perform the conveying-out of the processed substrate W from the first chuck 9 and the conveying-in of an unprocessed substrate W to the second chuck 12 as shown in FIG. 13A.

As described above, with the fourth preferred embodiment, the guide raising/lowering units 443 raise and lower the first upper guides 7 and the first lower guides 8. At the same time, the guide raising/lowering units 443 raise and lower the second upper guides 10 and the second lower guides 11. The guide raising/lowering units 443 move the first chuck 9 and the second chuck 12 in mutually opposite directions in regard to the vertical directions. The interval (interval in the vertical direction) between the first chuck 9 and the second chuck 12 is thereby increased and decreased. The guide raising/lowering units 443 are thus capable of moving a substrate W from the inverting path 405 to one hand H and moving a substrate W from another hand H to the inverting path 405 at the same time without moving the two hands H. Time required for transfer of substrates W between the substrate conveying robots IR and CR and the inverting path 405 can thus be shortened.

Although with the operation example described above, an example where transfers of the unprocessed W and the processed substrate W between the center robot CR and the inverting path 405 are performed successively has been described, transfers of the unprocessed substrate W and the processed substrate W may be performed at the same time by performing the same operations as those of the transfers of the substrates W between the indexer robot IR and the inverting path 405.

### Fifth Preferred Embodiment

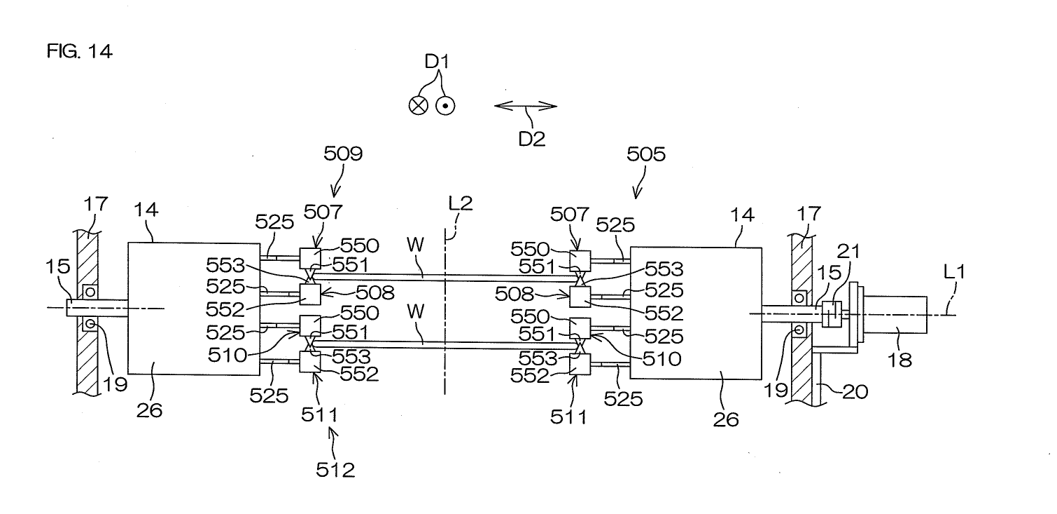

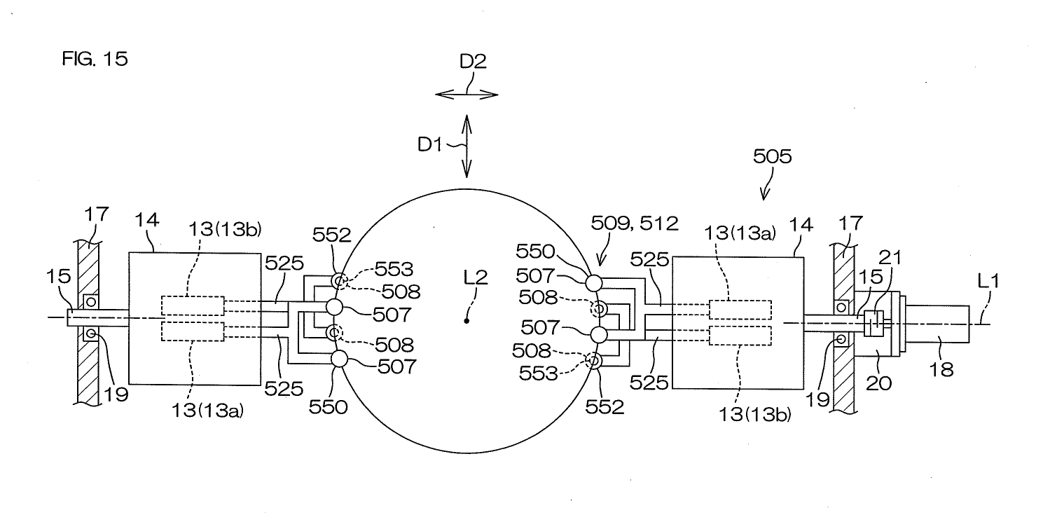

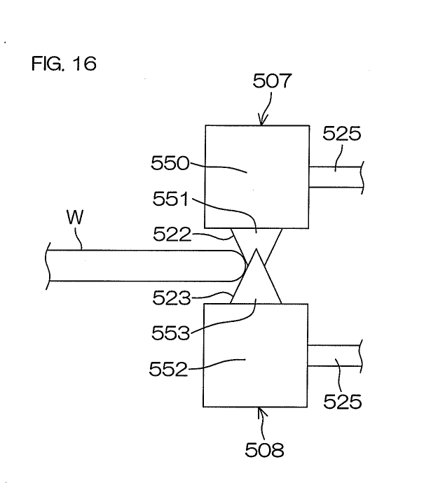

FIG. 14 is a schematic front view for describing an arrangement of an inverting path 505 according to a fifth preferred embodiment of the present invention. FIG. 15 is a schematic plan view for describing the arrangement of the inverting path 505 according to the fifth preferred embodiment of the present invention. FIG. 16 is an enlarged view of a portion of FIG. 14. In FIG. 14 to FIG. 16, component portions corresponding to portions indicated in FIG. 1 to FIG. 13D described above are provided with the same reference symbols as in FIG. 1, etc., and description thereof shall be omitted.

A principal point of difference of the fifth preferred embodiment with respect to the first preferred embodiment is the difference in the arrangements of the first chuck and the second chuck. That is, whereas in the first preferred embodiment, the first chuck and the second chuck are arranged from block-shaped guides, in the fifth preferred embodiment, the first chuck and the second chuck are arranged from cylindrical guides.

Specifically, the inverting path 505 (substrate inverting apparatus) includes a first chuck 509 and a second chuck 512 in place of the first chuck 9 and the second chuck 12 according to the first preferred embodiment. The first chuck 509 and the second chuck 512 are disposed between the two holding boxes 14. As shown in FIG. 14, the first chuck 509 is disposed above the second chuck 512. As shown in FIG. 15, the first chuck 509 includes four first upper guides 507 and four first lower guides 508. Likewise, the second chuck 512 includes four second upper guides 510 and four second lower guides 511. As in the first preferred embodiment, the second chuck 512 is merely disposed at a different height from the first chuck 509 and has an arrangement in common with the first chuck 509. The first chuck 509 shall thus mainly be described in the following description.

As shown in FIG. 14, the first upper guides 507 and the first lower guides 508 are disposed so as to be aligned with a peripheral edge portion of a single substrate W. The four first upper guides 507 are disposed at the same height. The four first lower guides 508 are disposed at the same height below the first upper guides 507. As shown in FIG. 15, two of the first upper guides 507 are disposed at the side of one of the supporting plates 17, and the remaining two first upper guides 507 are disposed at the side of the other supporting plate 17. Likewise, two of the first lower guides 508 are disposed at the side of one of the supporting plates 17, and the remaining two first lower guides 508 are disposed at the side of the other supporting plate 17.

As shown in FIG. 15, the first upper guides 507 disposed at the side of one of the supporting plates 17 face the first upper guides 507 disposed at the side of the other supporting plate 17 in a horizontal direction passing through the center of a substrate W. Likewise, the first lower guides 508 disposed at the side of one of the supporting plates 17 face the first lower guides 508 disposed at the side of the other supporting plate 17 in a horizontal direction passing through the center of the substrate W. The first upper guides 507 and the first lower guides 508 are disposed alternately in regard to a circumferential direction of the substrate W.

As shown in FIG. 16, the first upper guides 507 and the first lower guides 508 are cylindrical and are disposed in vertical orientations. Between the first upper guide 507 and the first lower guide 508, one has a shape that is vertically inverse to the shape of the other. Each first upper guide 507 includes an upper cylindrical portion 550 extending in the vertical direction and an upper conical portion 551 extending downward from a lower end of the upper cylindrical portion 550. Each first lower guide 508 includes a lower cylindrical portion 552 extending in the vertical direction and a lower conical portion 553 extending downward from an upper end of the lower cylindrical portion 552. The upper cylindrical portion 550 is disposed above the lower cylindrical portion 552. The upper conical portion 551 and the lower conical portion 553 are disposed at heights between the upper cylindrical portion 550 and the lower cylindrical portion 552. When viewed from a horizontal direction (conveying direction D1), the upper conical portion 551 and the lower conical portion 553 overlap partially. The substrate W is clamped in the horizontal orientation by point contacts of the upper conical portions 551 and the lower conical portions 553 with the substrate W.

Specifically, as shown in FIG. 16, each upper conical portion 551 has an upper inclined portion 522 (first upper inclined portion, second upper inclined portion), inclined obliquely upward toward the reference line L2, at the reference line L2 side. Each lower conical portion 553 has a lower inclined portion 523 (first lower inclined portion, second lower inclined portion), inclined obliquely downward toward the reference line L2, at the reference line L2 side. The upper inclined portion 522 is faced downward and the lower inclined portion 523 is faced upward. The upper inclined portion 522 and the lower inclined portion 523 are arranged to contact the peripheral edge portion of the substrate W. The substrate W is supported in the horizontal orientation by point contacts of the respective lower inclined portions 523 with the peripheral edge portion of the substrate W. Further, the substrate W is guided by the inclinations of the plurality of lower inclined portions 523 so that the center of the substrate W is positioned at a middle of two first lower guides 508. Yet further, the substrate W is restricted in movement in the horizontal direction and the vertical direction by the point contacts of the respective lower inclined portions 523 with the peripheral edge portion of the substrate W and point contacts of the respective upper inclined portions 522 with the peripheral edge portion of the substrate W.

As shown in FIG. 15, two first upper guides 507 are coupled to a supporting bracket 525 in common. Likewise, two first lower guides 508 are coupled to a supporting bracket 525 in common. The supporting bracket 525 supporting the two first upper guides 507 and the supporting bracket 525 supporting the two first lower guides 508 are disposed at different heights. Each supporting bracket 525 is coupled to a cylinder 13 housed inside each holding box 14. By the cylinders 13 moving the corresponding supporting brackets 525, the corresponding guides 507, 508, 510, and 511 are moved in the facing direction D2 between contacting positions at which the guides 507, 508, 510, and 511 contact the peripheral edge portion of the substrates W and the withdrawn positions at which the guides 507, 508, 510, and 511 are separated from the peripheral edge portion of the substrates W.

As described above, with the fifth preferred embodiment, the inverting path 505 moves the guides 507, 508, 510, and 511 horizontally as in the first preferred embodiment to clamp the substrate W. The inverting path 505 can thus be reduced in height in comparison to an arrangement in which the guides are moved vertically to perform clamping. Enlargement of the inverting path 505 can thereby be suppressed or prevented. Enlargement of the substrate processing apparatus 1 can thus be suppressed or prevented.

Although preferred embodiments of the present invention have been described above, the present invention is not limited to the contents of the above-described first to fifth preferred embodiments and can be variously modified within the scope of the appended claims. For example, with the first preferred embodiment, a case where the cylinders 13 (air cylinders) that are driven by pneumatic pressure move the guides in the facing direction D2 has been described. However, the linear actuators that move the guides in the facing direction D2 are not restricted to the cylinders 13, and may instead be solenoid actuators or other forms of actuators.

Also, with the first preferred embodiment, a case where the electric motor 18 that is driven by electric power rotates the guides around the inversion axis L1 has been described. However, the rotary actuator that rotates the guides around the inversion axis L1 may instead be a pneumatic actuator or other form of actuator.

Also, with the first preferred embodiment, a case where the output shaft of the electric motor 18 is coupled to the rotating shaft 15 via the joint 21 and the driving force of the electric motor 18 is transmitted to the rotating shaft 15 via the joint 21 has been described. However, the output shaft of the electric motor 18 and the rotating shaft 15 may instead be coupled by a belt transmission unit and the driving force of the electric motor 18 may be transmitted to the rotating shaft 15 via the belt transmission unit. In this case, the belt transmission unit may include a drive pulley coupled to the output shaft of the electric motor 18, an idler pulley coupled to the rotating shaft 15, and an endless belt wound around the drive pulley and the idler pulley.

Also, with the first preferred embodiment, a case where the first upper guides 7 are disposed above the first lower guides 8 and the first upper guides 7 and the first lower guides 8 are overlapped in a plan view has been described. However, the first upper guides 7 and the first lower guides 8 may be disposed so as not to be overlapped in a plan view. The same applies to the second upper guides 10 and the second lower guides 11.

Also, with the first preferred embodiment, a case where between the first upper guide 7 and the first lower guide 8, one has a shape that is vertically inverse to the shape of the other has been described. However, the shape of the first upper guide 7 and the vertically inverted shape of the first lower guide 8 may differ. The same applies to the second upper guide 10 and the second lower guide 11.

Also, with the first preferred embodiment, a case where the second upper guide 10 has a shape in common with the first upper guide 7 and the second lower guide 11 has a shape in common with the first lower guide 8 has been described. However, the second upper guide 10 may have a shape differing from that of the first upper guide 7. Likewise, the second lower guide 11 may have a shape differing from that of the first lower guide 8.

Also, with the first preferred embodiment, an operation example where the indexer robot IR conveys out a single substrate W held by the inverting path 5 and conveys a single substrate W into the inverting path 5 has been described. However, the indexer robot IR may convey two substrates W respectively into the first chuck 9 and the second chuck 12 or may convey out two substrates W held respectively by the first chuck 9 and the second chuck 12. In this case, the conveying-in of the two substrates W may be performed at the same time or at separate timings. Likewise, the conveying-out of the two substrates W may be performed at the same time or at separate timings. The same applies to the transfer of substrates W between the center robot CR and the inverting path 5. In a case where two substrates W are conveyed into the inverting path 5, the two substrates W held respectively by the first chuck 9 and the second chuck 12 are inverted at the same time.

Also, with the first preferred embodiment, a case where the inversion axis L1 is disposed at a height between the first chuck 9 and the second chuck 12 has been described. However, the inversion axis L1 may instead be disposed at height above or below the first chuck 9 and the second chuck 12 or may be disposed at the same height as the first chuck 9 or the second chuck 12.

Also, with the first preferred embodiment, a case where the substrate processing apparatus 1 processes a circular substrate has been described. However, the substrate processing apparatus 1 may be an apparatus that processes a polygonal substrate, such as a substrate for liquid crystal display.

Although the preferred embodiments of the present invention have been described in detail, these embodiments are merely specific examples used to clarify the technical contents of the present invention, and the present invention should not be understood as being limited to these specific examples, and the spirit and scope of the present invention are limited solely by the appended claims.

The present application corresponds to Japanese Patent Application No. 2011-184881 filed in the Japan Patent Office on Aug. 26, 2011, the entire disclosure of which is incorporated herein by reference.

What is claimed is:

1. A substrate inverting apparatus comprising:
a plurality of first lower guides respectively having a plurality of first lower inclined portions inclined obliquely downward toward a vertically extending reference line and supporting a substrate in a horizontal orientation by causing the plurality of first lower inclined portions to contact with a peripheral edge portion of the substrate;
a plurality of first upper guides respectively having a plurality of first upper inclined portions inclined obliquely upward toward the reference line and clamping the substrate in cooperation with the plurality of first lower guides by causing the plurality of first upper inclined portions to contact with the peripheral edge portion of the substrate at positions higher than positions at which the plurality of first lower inclined portions contact the peripheral edge portion of the substrate;
a guide moving mechanism that moves the plurality of first upper guides horizontally and moves the plurality of first lower guides horizontally; and
a guide rotating unit that rotates the plurality of first upper guides and the plurality of first lower guides around a horizontally extending inversion axis to invert the substrate clamped by the plurality of first upper guides and the plurality of first lower guides.

2. The substrate inverting apparatus according to claim 1, further comprising: a plurality of holding members, each holding the first upper guide and the first lower guide and being rotated around the inversion axis by the guide rotating unit.

3. The substrate inverting apparatus according to claim 2, further comprising: a plurality of rotating shafts respectively coupled to the plurality of holding members and rotatable around the inversion axis;
wherein the guide rotating unit is coupled to any one of the plurality of rotating shafts.

4. The substrate inverting apparatus according to claim 1, wherein the plurality of first upper guides are disposed respectively above the plurality of first lower guides.

5. The substrate inverting apparatus according to claim 1, further comprising: a plurality of second lower guides respectively having a plurality of second lower inclined portions inclined obliquely downward toward the vertically extending reference line and supporting a substrate, disposed at a different height from the substrate clamped by the plurality of first upper guides and plurality of first lower guides, in a horizontal orientation by causing the plurality of second lower inclined portions to contact with a peripheral edge portion of the substrate; and
a plurality of second upper guides respectively having a plurality of second upper inclined portions inclined obliquely upward toward the reference line and clamping the substrate in cooperation with the plurality of second lower guides by causing the plurality of second upper inclined portions to contact with the peripheral edge portion of the substrate at positions higher than positions at which the plurality of second lower inclined portions contact the peripheral edge portion of the substrate;
wherein the guide moving mechanism moves the plurality of second upper guides horizontally and moves the second lower guides horizontally, and
the guide rotating unit rotates the plurality of second upper guides and the plurality of second lower guides around the inversion axis to invert the substrate clamped by the plurality of second upper guides and the plurality of second lower guides.

6. The substrate inverting apparatus according to claim 5, further comprising: a plurality of holding members, each holding the first upper guide, the first lower guide, the second upper guide, and the second lower guide and being rotated around the inversion axis by the guide rotating unit.

7. The substrate inverting apparatus according to claim 6, further comprising: a plurality of rotating shafts respectively coupled to the plurality of holding members and rotatable around the inversion axis;
wherein the guide rotating unit is coupled to any one of the plurality of rotating shafts.

8. The substrate inverting apparatus according to claim 5, wherein the guide moving mechanism includes: a first upper guide moving unit that horizontally moves the first upper guides; a second upper guide moving unit that horizontally moves the second upper guides; a first lower guide moving unit that horizontally moves the first lower guides; and a second lower guide moving unit that horizontally moves the second lower guides.

9. The substrate inverting apparatus according to claim 5, wherein the guide moving mechanism includes: an upper guide moving module that horizontally moves the first upper guides and the second upper guides; and a lower guide moving module that horizontally moves the first lower guides and the second lower guides.

10. The substrate inverting apparatus according to claim 5, wherein the first upper guides, the first lower guides, the second upper guides, and the second lower guides are rotatable around the inversion axis relative to the guide moving mechanism.

11. The substrate inverting apparatus according to claim 5, further comprising: a guide raising/lowering unit that moves the first upper guides plus the first lower guides and the second upper guides plus the second lower guides in mutually opposite directions in regard to the vertical direction.

12. A substrate processing apparatus comprising:
the substrate inverting apparatus according to claim 1; and
a substrate conveying robot that performs conveying-in of a substrate to the substrate inverting apparatus and conveying-out of the substrate from the substrate inverting apparatus.

13. A substrate handling method comprising:
a first clamping step (A), of clamping a substrate by a plurality of first upper guides and a plurality of first lower guides, including the steps of: (A1) horizontally moving the plurality of first lower guides, having a plurality of first lower inclined portions inclined obliquely downward toward a vertically extending reference line, to make the plurality of first lower inclined portions contact a peripheral edge portion of the substrate; and (A2) horizontally moving the plurality of first upper guides, having a plurality of first upper inclined portions inclined obliquely upward toward the reference line, to make the plurality of first upper inclined portion contact the peripheral edge portion of the substrate at positions higher than positions at which the plurality of first lower inclined portions contact the peripheral edge portion of the substrate; and
(B) a first inverting step of inverting the substrate clamped by the first upper guides and the first lower guides by rotating the plurality of first upper guides and the plurality of first lower guides around a horizontally extending inversion axis.

14. The substrate handling method according to claim 13, further comprising: a first transfer step of vertically moving a hand that holds and conveys a substrate, relative to the first upper guides plus the first lower guides, to perform transfer of the substrate between the hand and the first upper guides plus the first lower guides.

15. The substrate handling method according to claim 14, wherein the first transfer step includes the steps of:
moving the first upper guides from contacting positions at which the first upper inclined portions contact the substrate to withdrawn positions at which the first upper guides are withdrawn in directions of moving away from the reference line; and
lowering the first lower guides relative to the hand to transfer the substrate from the first lower guides to the hand.

16. The substrate handling method according to claim 14, wherein the first transfer step includes the steps of:
moving the first upper guides from contacting positions at which the first upper inclined portions contact the substrate to withdrawn positions at which the first upper guides are withdrawn in directions of moving away from the reference line; and
raising the first lower guides relative to the hand to transfer the substrate from the hand to the first lower guides.

17. The substrate handling method according to claim 13, further comprising:
a second clamping step (C), of clamping a substrate by a plurality of second upper guides and a plurality of second lower guides at a height differing from the substrate clamped by the plurality of first upper guides and first lower guides, including the steps of: (C1) horizontally moving the plurality of second lower guides, having a plurality of second lower inclined portions inclined obliquely downward toward the vertically extending reference line, to make the plurality of second lower inclined portions contact a peripheral edge portion of the substrate; and (C2) horizontally moving the plurality of second upper guides, having a plurality of second upper inclined portions inclined obliquely upward toward the reference line, to make the plurality of second upper inclined portion contact the peripheral edge portion of the substrate at positions higher than positions at which the plurality of second lower inclined portions contact the peripheral edge portion of the substrate; and
(D) a second inverting step of inverting the substrate clamped by the second upper guides and the second lower guides by rotating the plurality of second upper guides and the plurality of second lower guides around a horizontally extending inversion axis.

18. The substrate handling method according to claim 17, further comprising: a second transfer step of vertically moving a hand that holds and conveys a substrate and the second upper guides plus the second lower guides relative to each other to perform transfer of the substrate between the hand and the second upper guides plus the second lower guides.

19. The substrate handling method according to claim 17, further comprising the step of: moving the first upper guides plus the first lower guides and the second upper guides plus the second lower guides in mutually opposite directions in regard to a vertical direction.
